(19) United States
(12) Patent Application Publication
(10) Pub. No.: US 2021/0308934 A1
(43) Pub. Date: Oct. 7, 2021

(54) NANOIMPRINTING ORGANO-METAL PEROVSKITES FOR OPTOELECTRONIC AND PHOTOVOLTAIC APPLICATIONS

(71) Applicant: Board of Regents, The University of Texas System, Austin, TX (US)

(72) Inventors: Anvar Zakhidov, McKinney, TX (US); Wenchuang Hu, Dallas, TX (US); Honglei Wang, Austin, TX (US); Ross Haroldson, Carrollton, TX (US); Balasubramaniam Balachandran, Dallas, TX (US)

(21) Appl. No.: 15/923,811

(22) Filed: Mar. 16, 2018

Related U.S. Application Data
(60) Provisional application No. 62/472,392, filed on Mar. 16, 2017.

(51) Int. Cl. B29C 59/02; C30B 29/12

(52) U.S. Cl. CPC B29C 59/022; B82Y 20/00; C30B 29/12; B29C 59/026

(57) ABSTRACT

A method for making a nanoimprinted perovskite film or a perovskite crystal. The method includes applying a solution onto a substrate, thereby forming a precursor film or a precursor crystal, wherein the solution comprises an organo-metal halide precursor in a solvent. The method also includes fabricating an organo-metal halide perovskite film or an organo-metal halide perovskite crystal, wherein fabricating includes annealing the precursor film or the precursor crystal, thereby at least partially evaporating the solvent. The method also includes imprinting the organo-metal halide perovskite film or the organo-metal halide perovskite crystal with a mold, thereby forming an imprinted film or an imprinted crystal. The method also includes separating the mold from the imprinted film or the imprinted crystal, thereby forming the perovskite film or the perovskite crystal.

### BACKGROUND INFORMATION

### 1. Field

The present disclosure relates to microscale and nanoscale materials and their processing, and to optoelectronic devices.

### 2. Background

Conventional inorganic perovskite is a class of crystal structure, exemplified by a calcium titanium oxide mineral composed of calcium titanate (CaTiO3). “Perovskites” lends its name to the class of compounds which have the same type of crystal structure as CaTiO3 (^{XII}A^{2+IV}B⁴⁺X²⁻₃) known as the perovskite structure. Many different cations and anions can be embedded in this structure, allowing for the development of diverse engineered materials.

### SUMMARY

The illustrative embodiments provide for a method for making a nanoimprinted perovskite film or a perovskite crystal. The method includes applying a solution onto a substrate, thereby forming a precursor film or a precursor crystal, wherein the solution comprises an organo-metal halide precursor in a solvent. The method also includes fabricating an organo-metal halide perovskite film or an organo-metal halide perovskite crystal, wherein fabricating includes annealing the precursor film or the precursor crystal, thereby at least partially evaporating the solvent. The method also includes imprinting the organo-metal halide perovskite film or the organo-metal halide perovskite crystal with a mold, thereby forming an imprinted film or an imprinted crystal. The method also includes separating the mold from the imprinted film or the imprinted crystal, thereby forming the perovskite film or the perovskite crystal.

The illustrative embodiments also provide for a nanoimprinted device including an imprinted organometal perovskite layer comprising one of a film and a crystal.

The illustrative embodiments also provide for a photovoltaic device. The photovoltaic device includes two electrically conductive electrode layers. The photovoltaic device also includes two transport layers respectively adjacent to the electrically conductive electrode layers. At least one of the electrode layers is optically transparent. The two transport layers are a hole transport layer (HTL) and an electron transport layer (ETL). The photovoltaic device also includes an imprinted organometal photoactive perovskite layer. The imprinted organometal perovskite layer is sandwiched between the two transport layers.

The illustrative embodiments also provide for a light emitting device (LED). The LED includes two electrically conductive electrode layers. At least one of the electrode layers is optically transparent. The also LED includes two transport layers respectively adjacent to the two electrically conductive electrode layers. The two transport layers are a hole transport layer (HTL) and electron transport layer (ETL). The also LED includes a light emissive imprinted organometal perovskite layer. The light-emissive imprinted organometal perovskite layer is sandwiched between the two transport layers. The two electrically conductive electrode layers are configured for charge injection into the light emissive imprinted organometal perovskite layer.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 shows a schematic of nanoimprinting lithography of perovskite thin films using a Si flat mold;

FIG. 2 shows a schematic of nanoimprinting lithography of perovskite thin films using a Si nanopillar mold;

FIG. 3 shows a schematic of nanoimprinting lithography of perovskite thin films using a Si nanograting mold;

FIG. 4 shows the temperature and pressure profile of the nanoimprinting lithography (NIL) process;

FIG. 5 shows a scanning electron micrograph of a nonimprinted perovskite thin film;

FIG. 6 shows a perovskite thin film imprinted with a flat Si mold;

FIG. 7 shows a perovskite thin film imprinted with a Si nanopillar mold;

FIG. 8 shows a perovskite thin film imprinted with a Si nanograting mold;

FIG. 9 shows an SEM image of freestanding perovskite nanorods peeled off from the thin perovskite film spin-coated on a Si surface;

FIG. 10 shows X-ray diffraction (XRD) of methylammonium lead triiodide (MAPbI3) perovskite non-imprinted film and nanoimprinted film using a nanograting mold over an area of 1 cm²;

FIG. 11 shows the UV-vis transmission of nonimprinted, flat-imprinted, nanohole, and nanograting imprinted MAPbI3 films;

FIG. 12 shows the reflectance spectra of nonimprinted, flat-imprinted, nanohole, and nanograting imprinted MAPbI3 films;

FIG. 13 shows the steady-state photoluminescence of MAPbI3 thin non-imprinted film, nanograting, and nanohole;

FIG. 14 shows the time-resolved photoluminescence of MAPbI3 thin non-imprinted film, nanograting, and nanohole;

FIG. 15 is an image of the imprinted perovskite nanohole array sample;

FIG. 16 shows a 3-D schematics of a tf-PSPD (thin-film perovskite photodetector);

FIG. 17 shows a 3-D schematic of a flat-PSPD;

FIG. 18 shows a 3-D schematic of a nanohole-PSPD;

FIG. 19 shows a 3-D schematic of a nanograting-PSPD;

FIG. 20 shows a schematic illustration of the nanograting-PSPD;

FIG. 21 shows the temporal current characteristics of nanograting-PSPD at 7.27 mW/cm² halogen light illumination with a bias voltage of 1 V;

FIG. 22 shows the I-V characteristics of nanograting-PSPD with 0.11 to 7.27 mW/cm² halogen light illumination, and the inset shows the current as a function of irradiance;

FIG. 23 shows the I-V characteristics of tf-PSPD, flat-PSPD, nanohole-PSPD, and nanograting PSPD at 7.27 mW/cm² halogen light illumination in logarithmic scale, and the inset shows the same curves in linear scale;

FIG. 24 shows I-V characteristics of a tf-PSPD in dark environment and under 0.11 mW/cm² to 7.27 mW/cm² halogen light illumination;

FIG. 25 shows I-V characteristics of multiple tf-PSPDs under 7.27 mW/cm² halogen light illumination;

FIG. 26 shows I-V characteristics of multiple flat-PSPDs under 7.27 mW/cm² halogen light illumination;

FIG. 27 shows I-V characteristics of multiple nanohole-PSPDs under 7.27 mW/cm² halogen light illumination;

FIG. 28 shows I-V characteristics of multiple nanograting-PSPDs under 7.27 mW/cm² halogen light illumination;

FIG. 29 shows I-V characteristics of multiple no mold-PSPDs under 7.27 mW/cm² halogen light;

FIG. 30 shows a current plot of all four types of devices under 7.27 mW/cm² halogen light illumination with a bias voltage of 1V, wherein the mean values with standard deviation are indicated in the plot for each type;

FIG. 31 shows a performance comparison between tf-PSPDs with 10 minutes thermal annealing and 30 minutes thermal annealing of photocurrent under 7.27 mW/cm² halogen light illumination;

FIG. 32 shows a performance comparison between tf-PSPDs with 10 minutes thermal annealing and 30 minutes thermal annealing of photocurrent under 7.27 mW/cm² dark current;

FIG. 33 shows a performance comparison between tf-PSPDs with 10 minutes thermal annealing and 30 minutes thermal annealing of photocurrent under 7.27 mW/cm² on/off ratio;

Table 1 is a table showing a performance and geometry comparison of Tf-PSPD, flat PSPD, nanohole-PSPD, and nanograting-PSPD devices;

FIG. 34 shows a plot of photodetector current vs LED forward current at λ=466 nm;

FIG. 35 shows a plot of photodetector current vs LED forward current at λ=635 nm;

FIG. 36 shows a plot of photodetector current vs irradiance at λ=466 nm;

FIG. 37 shows a plot of photodetector current vs irradiance at λ=635 nm;

FIG. 38 shows an irradiance-dependent responsivity plot at λ=466 nm;

FIG. 39 shows an irradiance-dependent responsivity plot at λ=635 nm;

Table 2 shows a table of complete performance of tf-PSPDs, flat-PSPDs, nanohole-PSPDs, and nanograting-PSPDs under 7.27 mW/cm² halogen light illumination;

FIG. 40 is a graph of XRD results of a perovskite quantum dot sample imprinted at 100° C. versus a non-imprinted thin film sample as a control;

FIG. 41 is a representation of an electron microscope image of an imprinted perovskite quantum dot sample with formed nanograting;

FIG. 42 is a representation of an electron microscope image of an imprinted perovskite quantum dot sample with formed nanoholes;

FIG. 43 is a graph of XRD results of the perovskite quantum dot sample imprinted at 20° C. versus a non-imprinted thin film sample as a control;

FIG. 44 is a representation of an electron microscope image of an imprinted acetated perovskite sample;

FIG. 45 is a representation of an optical microscope image of an imprinted perovskite PVP composite sample;

FIG. 46 is a representation of an optical microscope image of an imprinted perovskite PVP composite sample; and

FIG. 47 is a representation of an electron microscope image created by nanoimprint lithography (NIL) of a single crystal.

### DETAILED DESCRIPTION

### Definitions

As used herein, the following acronyms and terms have the following definitions:

“2D” stands for “two-dimensional”.

“3D” stands for “three-dimensional”.

“A” when used as a unit of measurement stands for “ampere”, a unit of measurement for an electric current.

“BABr” stands for “n-Butylammonium Bromide”.

“c” when used with a unit of measurement stands for “centi-” or one hundredth of a unit of measurement.

“C” when used as a unit of measurement stands for “Celsius,” a unit of measurement for temperature.

“DMF” stands for “dimethylformamide”.

“DMSO” stands for “N,N′-dimethyl sulfoxide”.

“DSC” stands for “differential scanning calorimetry”.

“ETL” stands for “electron transport layer.”

“eV” stands for “electron volt”, a unit of electrical energy.

“f” when used with a unit of measurement stands for “femto-”, or one quadrillionth (10⁻¹⁵) of a unit of measurement.

“FDTS” stands for “perfluorodecyltrichlorosilane” or any of 1H,1H,2H,2H-perfluorodecyltrichlorosilane.

“GDL” stands for “γ-butyrolactone”.

“HTL” stands for “hole transport layer”.

“Hz” stands for “Hertz”, a unit of frequency.

“I” when used as a unit of measurement stands for “current”, a unit of a flow of an electric charge.

“IPS” stands for “intermediate polymer stamp”.

“L” when used as a unit of measurement stands for “liter,” a unit of measurement for volume.

“LED” stands for “light emitting diode”.

“m” when used with a unit of measurement stands for “milli-”, or one thousandth of a unit of measurement.

“m” when used as a unit of measurement stands for “meter”, a unit of length.

“M” when used as a unit of measurement stands for “molar”, a unit of measurement for concentration in a solution.

“M” when used with a unit of measurement stands for “mega-”, or one million of a unit of measurement.

“MAC” stands for “acetaldehyde”.

“min” stands for “minute”.

“MSM” stands for “metal-semiconductor-metal”.

“n” when used with a unit of measurement stands for “nano-”, or one billionth of a unit of measurement.

“NIL” stands for “nanoimprint lithography”.

“OMH” stands for “organo-metal halide.”

“p” when used with a unit of measurement stands for “pico-”, or one trillionth of a unit of measurement.

“Pa” when used as a unit of measurement stands for “Pascal,” a unit of measurement for pressure.

“PDMS” stands for “polydimethylsiloxane”.

“PEG” stands for “polyethylene glycol”.

“PEO” stands for “polyethylene oxide”.

“PL” stands for “photoluminescence”.

“PSPD” stands for “perovskite photodetector”.

“PTFE” stands for “polytetrafluoroethylene”.

“PVP” stands for “Polyvinylpyrolidone”.

“QD” stands for “quantum dot”.

“RPM” or “r.p.m.” stands for “revolutions per minute”.

“s” stands for “second”.

“SEM” stands for “scanning electron microscopy.”

“tf-PSPD” stands for “thin film perovskite photodetector”.

“V” when used as a unit of measurement stands for “Volt”, a unit of measurement for an electric field.

“W” when used as a unit of measurement stands for “Watt”, a unit of measurement for electrical power.

“XRD” stands for “X-ray diffraction”.

The terms “II-VI” and “III-V” refers to elements in columns 2-4 and columns 3-5, respectively, of the periodic table of the elements.

“λ” is the Greek letter “lamda”, which is used herein to refer to wavelength.

“μ” when used with a unit of measurement stands for “micro-”, or one millionth of a unit of measurement.

Other acronyms reference the proper initials of elements on the periodic table of the elements.

### Overview

The illustrative embodiments relate to a sub-class of perovskite materials, known as lead halide perovskites, which have a softer structure than commonly known perovskites. The illustrative embodiments may also relate to hybrid organic-inorganic perovskites, known as organo-metal halide perovskites, which has an organic A-cation, making it a softer structure. The illustrative embodiments may also be applied to inorganic A-cation types of perovskites, such as those that include cesium.

One example of this invention is a method for making a nanoimprinted organometal halide perovskite thin film for photovoltaic and optoelectronic applications. The method begins with spin coating a solution of precursors onto a substrate, the solution comprising an organolead halide precursors in a volatile solvent. The method proceeds to fabricating a damp thin-film, wherein fabricating the damp thin-film includes annealing the spin-coated film of precursor solution, thereby partially evaporating the volatile solvent and converting a precursor into organolead perovskite. After fabricating the damp thin-film, the method proceeds to imprinting the damp thin film, wherein imprinting the damp thin-film includes pressing a mold onto the damp thin film while heating the imprinted thin-film and repeating the process by applying the sequential steps of increasing pressure and temperature increments. After imprinting the damp thin-film, the method proceeds to separating the mold from the imprinted thin-film, leaving a nanoimprinted pattern, (such as nanograting or nanoholes array) on the organometal halide perovskite film.

As indicated above, this invention is related to the field of nanoscale materials and their processing. This invention is also related to the field of optoelectronic devices.

Organo-metal halide (OHP) perovskites have emerged as a promising material for next-generation optoelectronic and photovoltaic applications with low cost and high performance. However, the perovskite polycrystalline film morphology has limited the optoelectronic device performance. Improving perovskite crystallinity is crucial to further enhance its optoelectronic properties. Meanwhile, nanoscale photodetectors have attracted tremendous attention towards realizing of miniaturized optoelectronic system as they offer high sensitivity, ultra-fast response and capability to detect beyond the diffraction limit.

Photodetectors which can convert light into electrical signals play an important role in a variety of applications, such as optical communication, digital imaging and environment monitoring. Nanoscale photodetectors allow for integration of photodetectors with state-of-art IC chips while simultaneously providing high sensitivity and ultra-fast response due to high photodetector surface-to-volume ratio and reduced conductive channel dimensions. Imaging systems with nanoscale pixels may even exhibit resolution beyond the diffraction limit. Materials that are compatible with conventional silicon electronics or other flexible substrate are especially attractive. Until recently, most of the nanostructured photodetectors reported used inorganic materials such as carbon nanotubes, group II-VI compounds, and group III-V compounds, all of which require time-consuming and uneconomic fabrication processes such as the vapor-liquid-solid method.

Organolead halide perovskite, an organic-inorganic hybrid material, is a promising material for next-generation optoelectronic devices. It has long carrier diffusion length, high carrier mobility and a large absorption coefficient over broad range of wavelengths (from ultraviolet to near infrared). perovskites are solution processable, enabling cost-effective fabrication. Among the various type of perovskite photodetector structures reported, the planar metal-semiconductor-metal (MSM) structure is notably simple and easy to fabricate. The first perovskite MSM photodetector was reported by Hu et al. which utilized an ITO-perovskite-ITO structure and achieved a photo responsivity of 3.49 A/W, 0.0367 A/W at 365 nm and 780 nm with a bias voltage of 3 V respectively.

Optoelectronic performance of a perovskite photodetector is influenced by its charge carrier diffusion length and mobility, which can be improved with better crystalline quality and fewer defects. However, sophisticated techniques used to attempt production of perovskite single crystals do not remedy existing difficulties with optoelectronic integration and mass production problems.

An aspect of this invention is a method for making a nanoimprinted perovskite thin film. The method begins with spin coating a solution onto a substrate, the solution comprising an organolead halide or its precursors in a volatile solvent. The method proceeds to fabricating a damp thin-film, wherein fabricating the damp thin-film includes annealing the spin-coated solution, thereby partially evaporating the volatile solvent. After fabricating the damp thin-film, the method proceeds to imprinting the damp thin film, wherein imprinting the damp thin-film includes pressing a mold onto the damp thin film while heating the imprinted thin-film under applied pressure. After imprinting the damp thin-film, the method proceeds to separating the mold from the imprinted thin-film. The process will leave the perovskite damp film as a nanoimprinted pattern of desired geometry such as nanograting or nanohole array.

### EXAMPLES

One example aspect of this invention is a method for making a nanoimprinted perovskite thin film. The method begins with spin coating a solution onto a substrate thereby forming a precursor film, wherein the solution comprises an organo-metal halide precursor in a volatile solvent. According to an embodiment of the invention, the organo-metal halide may be methylammonium lead triiodide (CH3NH3PbI3 or MAPbI3), methylammonium lead tribromide (CH3NH3PbBr3 or MAPbBr3), formamidinium lead triiodide (NH2CHNH2PbI3 or FAPbI3), formamidinium lead tribromide (NH2CHNH2PbBr3 or FAPbBr3), cesium lead triiodide (CsPbI3), cesium lead tribromide (CsPbBr3), or mixtures thereof. The substrate may be a silicon substrate. The volatile solvent may be a non-aqueous organic solvent such as, for example, an acetate-based solvent. The non-aqueous solvent may also be dimethylsulfoxide (DMSO), dimethylformamide (DMF), gamma-butyrolactone (GBL) or a mixture of these solvents.

After the spin-coating procedure, the method proceeds to applying toluene onto the precursor film before annealing.

After applying toluene, the method proceeds to fabricating a damp thin-film. Fabricating the damp thin-film includes annealing the spin-coated solution, thereby partially evaporating the volatile solvent. The damp thin-film is a perovskite thin-film. According to an embodiment of this invention, annealing may involve heating at a temperature of 100° C. for 20 minutes.

After the film fabricating step, the method proceeds to imprinting the damp thin film. The mold may be coated with an anti-adhesive. According to another embodiment of the invention, the mold may include silicon, silicon dioxide, polydimethylsiloxane (PDMS), and metal. The mold may be selected from a group of microscale and/or nanoscale structures consisting of pillars, holes, and gratings.

According to an embodiment of the invention, imprinting the damp thin film may include pressing a mold onto the damp thin-film at a pressure, such as 7 MPa, while heating the imprinted thin-film at a temperature, such as 100° C. Imprinting the damp thin-film may involve increasing the pressure and temperature by increments. Increasing the pressure may involve increasing the pressure at increments of between 0.5 MPa and 3 MPa up to 7 MPa. Increasing the temperature may involve increasing the temperature at increments of between 5° C. to 40° C., up to 130° C. The maximum temperature used in the imprinting step may vary depending on the composition of the particular organo-metal perovskite. For example, for organometal halide perovskites as FAPbBr3, maximum temperature can be around 120° C. to 130° C. The maximum temperature would depend on the decomposition temperature of the specific organometal halide perovskite,

After the imprinting step, the method proceeds to separating the mold from the imprinted thin-film.

Another example aspect of this invention is a photodetector device. The device includes two metal layers and an imprinted thin-film layer. The imprinted thin-film layer is sandwiched between the two metal layers. Furthermore, the imprinted thin-film layer is fabricated using the methods described above.

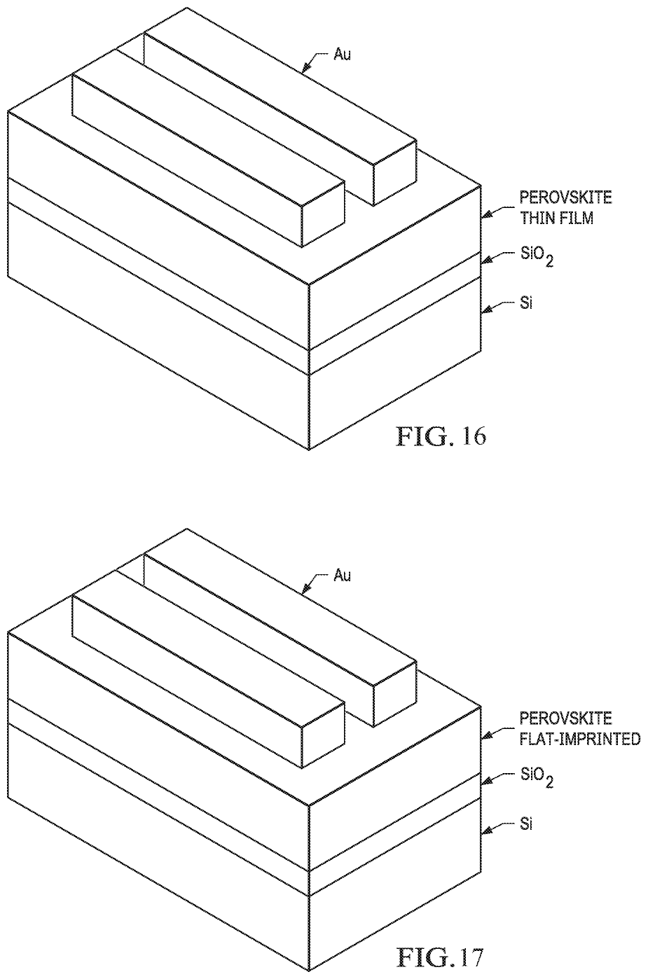

A second example aspect of the current invention is a photodetector device which includes two metal layers and an imprinted thin-film organometal perovskite layer. The imprinted thin-film layer may be sandwiched between the two-metal layer and may be fabricated using the methods described above. Another photodetector structure has the imprinted perovskite film on top of or underneath a pair of patterned electrodes, as illustrated in FIG. 16.

A third example aspect of the current invention is a photovoltaic device which includes two electrically conductive electrode layers, two transport layers, and an imprinted thin-film organometal perovskite layer. The two transport layers, corresponding to a hole transport layer (HTL) and electron transport layer (ETL), may be adjacent to the conductive electrode layers. The imprinted thin-film organometal layer may be sandwiched between the two transport layers, and may be fabricated using the methods described above. According to an embodiment of the invention, one of the electrode layers is optionally transparent.

A fourth example aspect of the current invention is a light emitting device which includes two electrically conductive electrode layers, two transport layers, and a light-emissive imprinted thin-film organometal perovskite layer. The two transport layers, corresponding to a hole transport layer (HTL) and electron transport layer (ETL), may be adjacent to the conductive electrode layers. The imprinted thin-film organometal layer may be sandwiched between the two transport layers, and may be fabricated using the methods described above. The conductive electrode layers may be configured for charge injection into the light emissive imprinted thin-film organometal perovskite layer. According to an embodiment of the invention, one of the electrode layers is optionally transparent.

### Example 1

Perovskite Thin Film Preparation.

The perovskite solution was prepared by dissolving a 1:1 molar ratio of PbI2 and CH3NH3I in a 7:3 volume ratio of γ-butyrolactone:N,N′-dimethyl sulfoxide solvent mixture in a N2 glovebox. The resulting perovskite concentration was 1.2 M. The solution was heated for 24 h at 60° C. The solution was then spincoated onto the Si substrates with 100 nm thick thermal SiO₂ that was previously ultrasonically cleaned with acetone and treated by oxygen plasma. The spin-coating was a two-step process—22 seconds at 1000 r.p.m. and 22 seconds at 5000 r.p.m. A 350 mL amount of anhydrous toluene was dropped on the film after 12 s in the second spin-coating step. The sample was then annealed on a hot plate at 100° C. for 10 min, during which solvents were evaporated and a dense and uniform MAPbI3 film was formed with a thickness of about 265 nm.

### Example 2

Nanoimprinting of Perovskite Films.

The Si flat, nanopillar, and nanograting molds were first treated with FDTS in n-heptane solvent for 5 min and then cleaned with acetone and blow dried with N2. The molds were then annealed at 100° C. for 20 min. Monolayer FDTS was formed on the Si molds, which served an antiadhesive purpose in the NIL process. The Si flat mold, nanopillar mold, and nanograting mold were then placed on the perovskite thin-film-coated substrate at different areas in a single process. The imprint utilized a multistep process: 90 s at a temperature of 35° C. and a pressure of 2 MP; 180 s at a temperature of 55° C. and a pressure of 4 MPa; 180 s at a temperature of 75° C. and a pressure of 6 MPa; and then, importantly, 1200 s at a temperature of 100° C. and a pressure of 7 MPa. The pressure was kept at 7 MPa while the chamber was cooled to a temperature of 35° C. The nanoimprinting process was then finished, and perovskite nanostructures were formed as a negative replication of the Si molds.

### Example 3

Fabrication of a Metal-Semiconductor-Metal Photodetector.

SiO₂ (100 nm) was thermally grown on a (100) Si wafer. perovskite thin films and nanoimprinted samples were prepared as described previously. A 300 nm thick gold film was deposited on the perovskite samples in an e-beam evaporator using a shadow mask. The gap between the gold electrode pairs was 25 μm in length and 100 μm in width. The effective photodetector area was 2.5×10⁻⁵ cm².

### Example 4

Characterization of Photodetector Devices.

A Keithley 4200 and a Cascade probe station were used to characterize the perovskite photodetectors. The devices under a dark environment and different illumination conditions were tested. A 150 W halogen lamp was used for illumination for all the devices. A blue LED with a peak wavelength of 466 nm and a red LED with a peak wavelength of 635 nm were used for the responsivity test of the nanograting-PSPD and tf-PSPD devices. The illumination light intensity was calibrated with a commercial Si photodiode.

### Example 5

Characterization of Nanoimprinted and Nonimprinted Perovskite Thin Films.

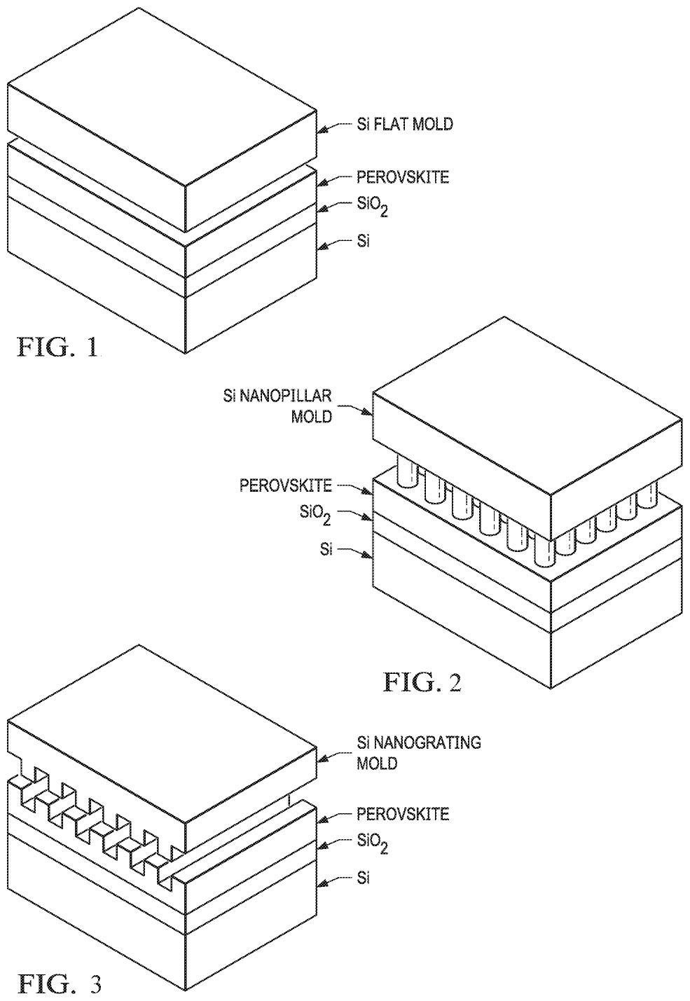

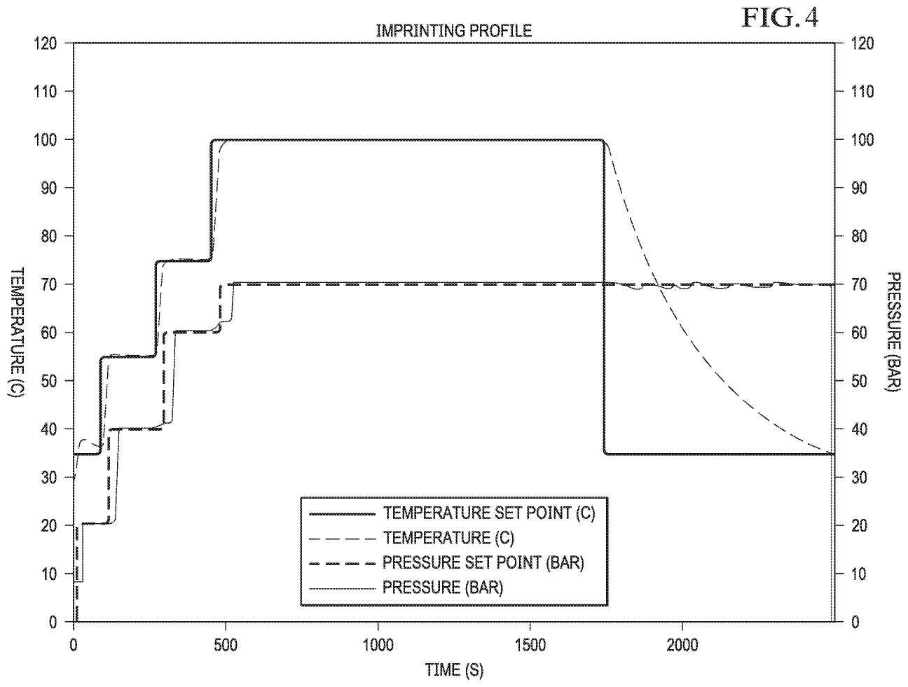

As described above, a modified solvent-engineering method was used for MAPbI3 perovskite deposition. As described, this method utilizes a mixture of γ-butyrolactone (GBL) and N,N′-dimethyl sulfoxide (DMSO) as solvents of methylammonium lead halide perovskite for spincoating followed with a toluene drip while spinning, which allows formation of a homogeneous perovskite layer after thermal annealing. In this study, (100) Si with 100 nm thick thermal oxide (SiO₂ thermally grown on “crystalline silicon” having Miller index of 100, also known as a (100) Si wafer) was used as the substrate. After spin-coating and dripping with toluene, the sample was annealed at 100° C. for 10 min, which subsequently drove out most of the solvent and formed a perovskite thin film with a thickness of 265 nm. One of the samples was imprinted, as illustrated in FIGS. 1-3. Three different Si molds were used to compare different structures. A flat surface (FIG. 1), nanopillar (FIG. 2), and nanograting (FIG. 3) structures were first treated with an antiadhesion monolayer of 1H,1H,2H,2H-perfluorodecyltrichlorosilane (FDTS). The molds were then placed on the perovskite thin film on different areas in a single process to ensure the same conditions applied to all molds. The samples were imprinted with a profile of conditions illustrated in FIG. 4. NIL was performed at a temperature of 100° C. and a pressure of 7 MPa for 20 min. Reference samples with as-spin-coated perovskite thin films without NIL treatment were also prepared.

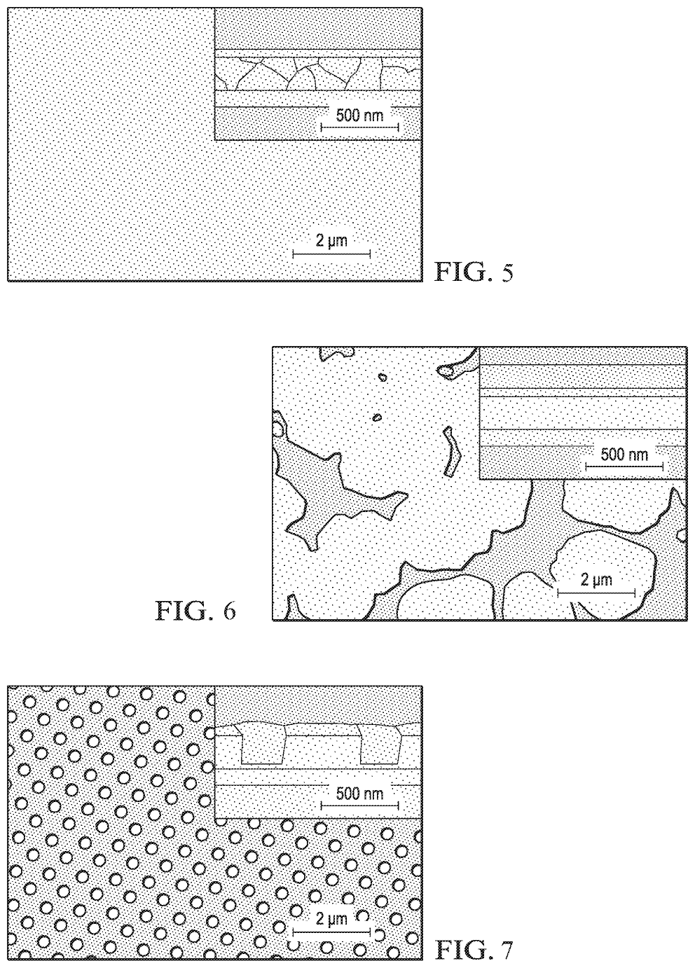

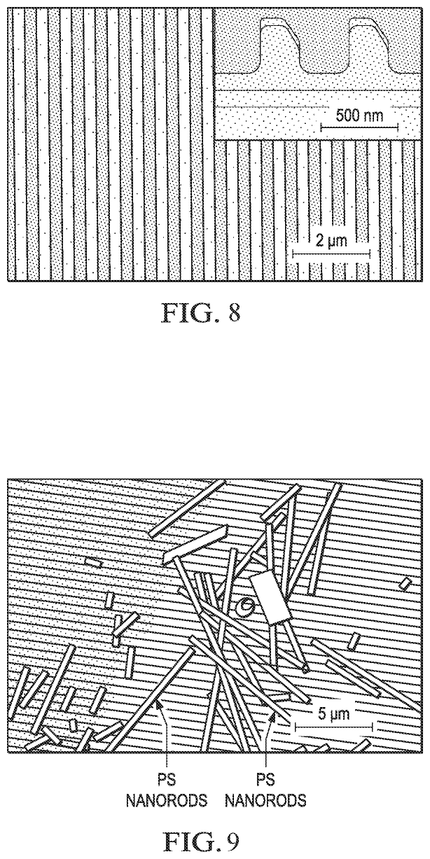

FIGS. 5-8 show the morphology of both the nonimprinted (FIG. 5) and imprinted films (FIGS. 6-8), as observed via scanning electron microscopy (SEM). The well-defined perovskite nanohole structures (FIG. 7) and nanograting structures (FIG. 8) were negative replications of the Si nanopillar mold and nanograting mold, respectively. The nanoholes have a patterned diameter and pitch of 275 and 600 nm, respectively, while the patterned width and pitch of nanograting are 270 and 600 nm, respectively. The SEM cross-section image reveals a depth of 315 nm with almost no residual layer for the nanoholes and a structure depth of 300 nm and residual layer thickness of 130 nm for the nanogratings. No obvious perovskite volume change is observed after NIL. The results have demonstrated that although perovskite is an ionic solid and does not have a glass transition behavior like polymers, it can be successfully patterned by NIL, as it can deform and fill in mold cavities upon applied heat and pressure.

Morphologic improvement by NIL is also revealed. From both top the view and cross-section view, the non-imprinted film (FIG. 5) shows small crystal grains and clear grain boundaries, while the nanoimprinted films (FIGS. 6-8) show larger grain size and smoother surface. Most notably, film imprinted using the nanograting mold shows almost invisible grain boundaries (FIG. 8). FIG. 9 shows free-standing nanorods stripped during mold release. The nanorods appear to have a dramatic morphologic difference compared with the residual layer. It is likely that with multidimensional confinement during nanoimprinting the nanorods have been formed with significantly better crystallinity than the underlying residual layer.

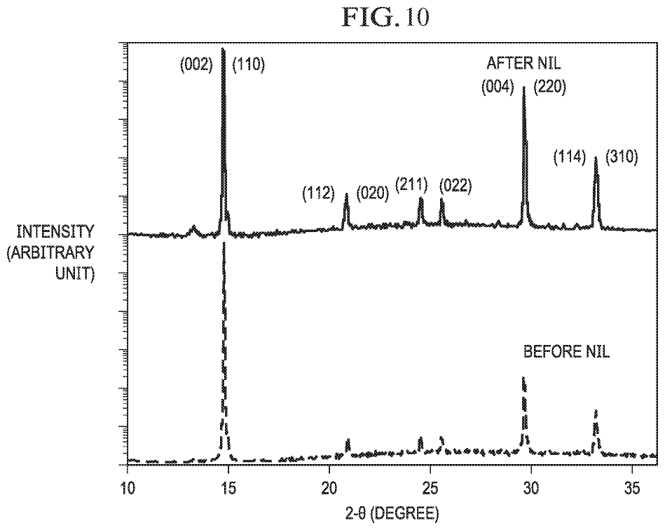

To confirm the improved structural order and crystallinity, another set of non-imprinted perovskite and imprinted perovskite samples were analyzed with X-ray diffraction (XRD), and the results are presented in FIG. 10. The sharp (220) reflection indicates the crystallinity of the imprinted MAPbI3 films. The crystallite sizes of the non-imprinted and nanoimprinted films were determined to be 68 and 188 nm, respectively. The improved crystallinity of nanoimprinted perovskite is clearly shown in the X-ray diffraction patterns.

Both microscopic images and diffraction analysis have confirmed the positive effect of NIL on perovskite crystallinity. A simple hypothesis is that during nanoimprinting with elevated temperature and pressure the perovskite small grains slide toward the mold cavities and collide with each other, which forms bigger grains and defects such as dislocations, disclinations, and vacancies are reduced. Another explanation is that the grain boundaries have been pushed to the perovskite and mold interface during nanoimprinting and therefore crystal grains are redefined based on the mold structures.

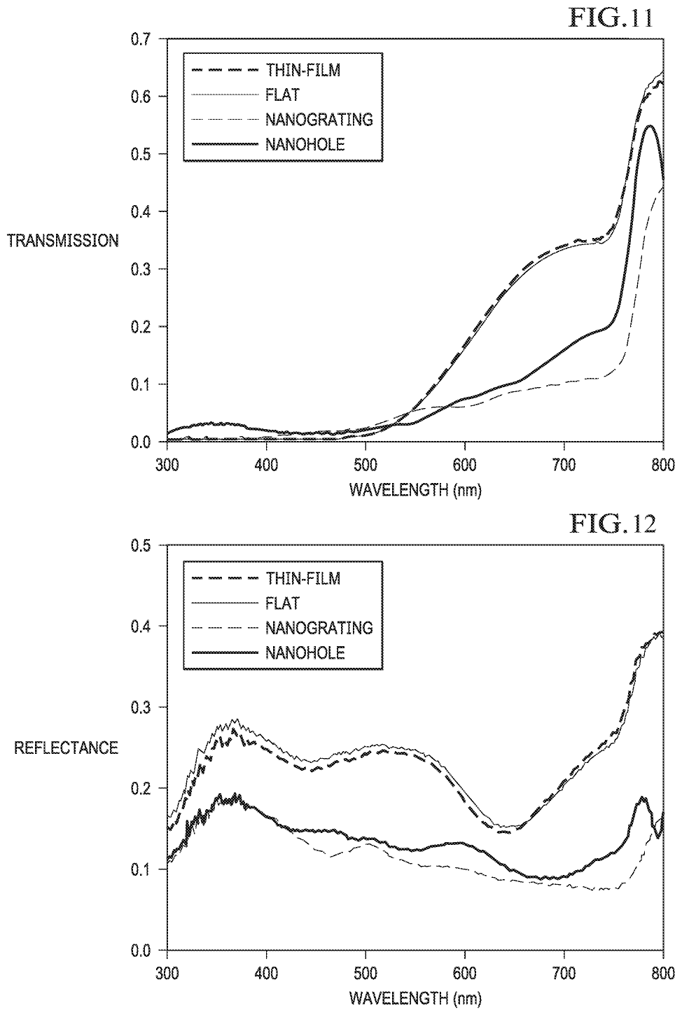

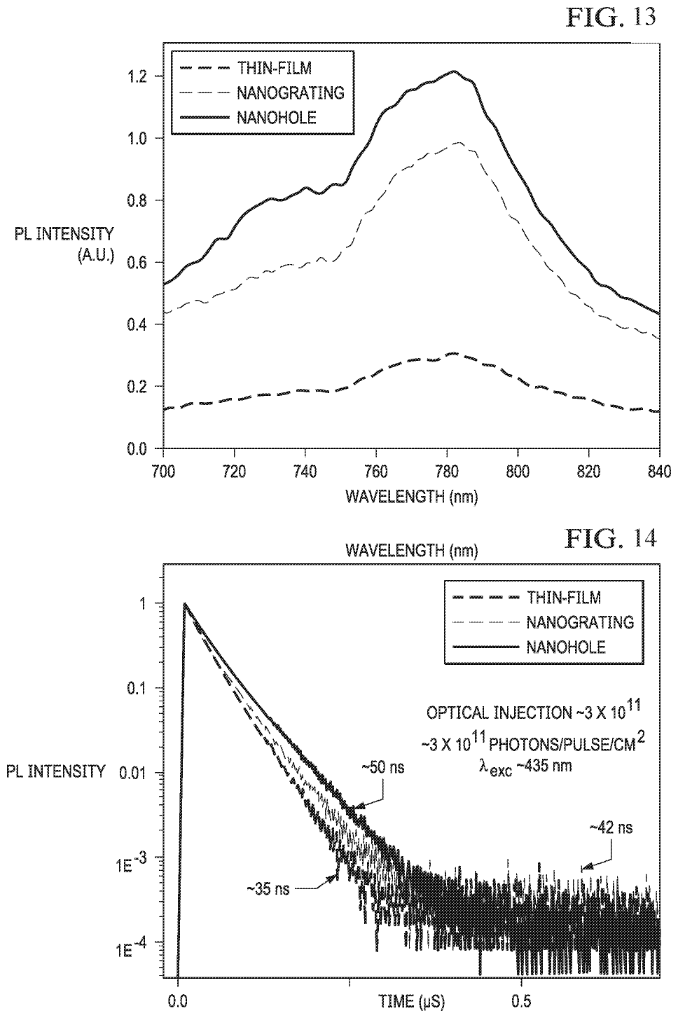

The optical properties of both non-imprinted and nanoimprinted films were also investigated by characterizing the transmission (FIG. 11), reflectance (FIG. 12), photoluminescence (PL) (FIG. 13), and PL lifetime (FIG. 14) of perovskite films on glass substrates. The films imprinted with nanoholes and nanogratings show significantly reduced reflectance for the whole spectrum and reduced transmission in the wavelength range of 550 to 800 nm. These results indicate that favorable photon trapping in perovskites and therefore higher optical absorption is feasible using nanoimprinting lithographic techniques alongside proper mold nanostructure design.

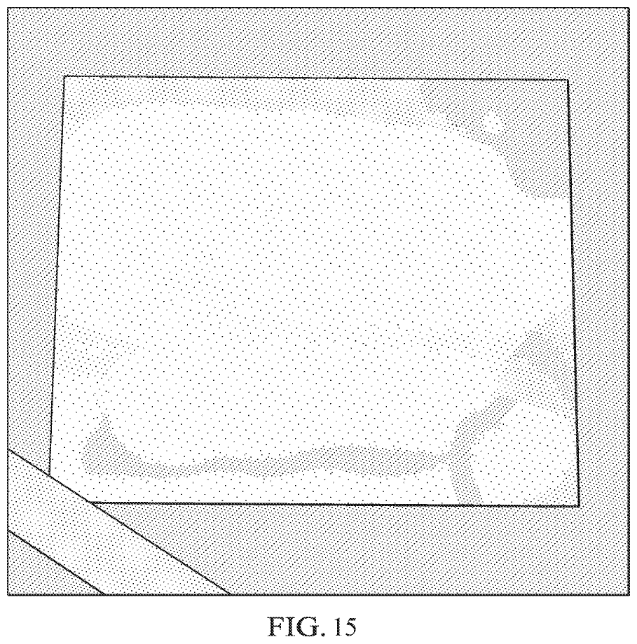

FIG. 15 shows iridescence of the patterned nanohole sample due to 2D photonic crystal effects, suggesting reasonable uniformity of NIL patterning across the 1 cm² imprinted area, while the areas appearing dark represents incomplete NIL or defects of nanoimprinted film.

The photoluminescence emission peak of the imprinted thin-films [non-imprinted] is located around 780 nm (1.59 eV) (FIG. 13). The nanoimprinted perovskites demonstrate better spontaneous emission properties with approximately 3-fold improvement for imprinted nanogratings and 4-fold improvement for imprinted nanoholes when compared with the non-imprinted thin films. The time-resolved photoluminescence acquired using a time-correlated single photon counting method (excitation laser wavelength 435 nm, pulse width 100 fs, repetition rate 1 MHz), as presented in FIG. 14, demonstrates improved photoluminescence lifetime of nanoimprinted thin-films: lifetime increases from a perovskite thin film (35 ns) to imprinted nanogratings (42 ns) and nanoholes (50 ns).

### Example 6

Characterization of Nanoimprinted and Nonimprinted Perovskite Photodetectors.

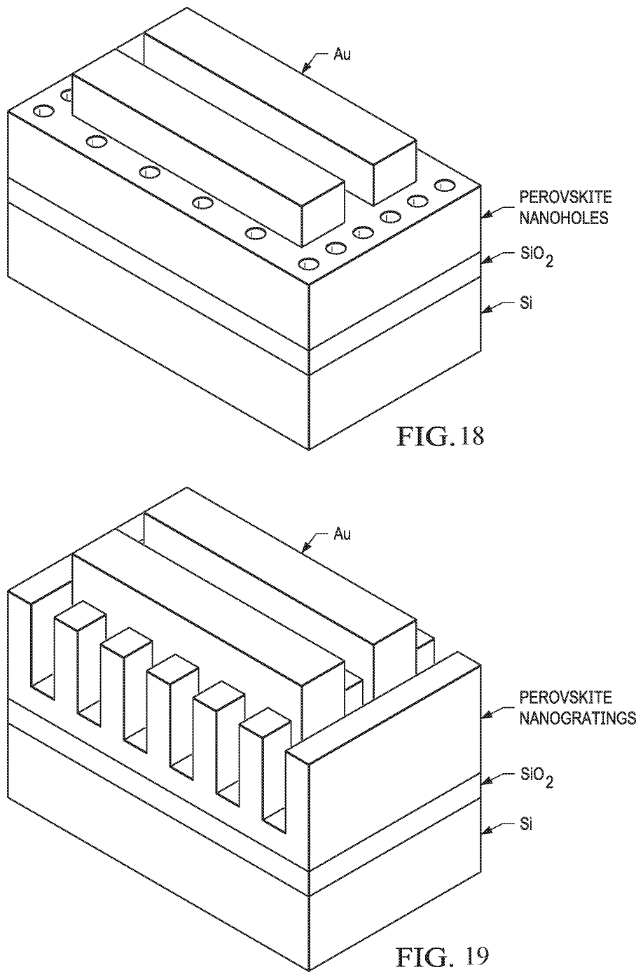

In order to evaluate the optoelectronic performance of NIL-imprinted perovskites, metal-semiconductor-metal photodetectors were fabricated by evaporating 300 nm thick gold electrodes with a 25 μm electrode gap on both imprinted and nonimprinted perovskite samples. The width of the electrode gap is 100 μm. Devices having four different types of film morphology were studied: the conventional non-imprinted thin-film perovskite photodetector (tf-PSPD) (FIG. 16), flat mold imprinted perovskite photodetector (flat-PSPD, FIG. 17), nanohole perovskite photodetector (nanohole-PSPD, FIG. 18), and nanograting perovskite photodetector (nanograting-PSPD, FIG. 19). The photoelectrical characteristics of four different types of photodetectors were obtained under the same test configuration at room temperature in air.

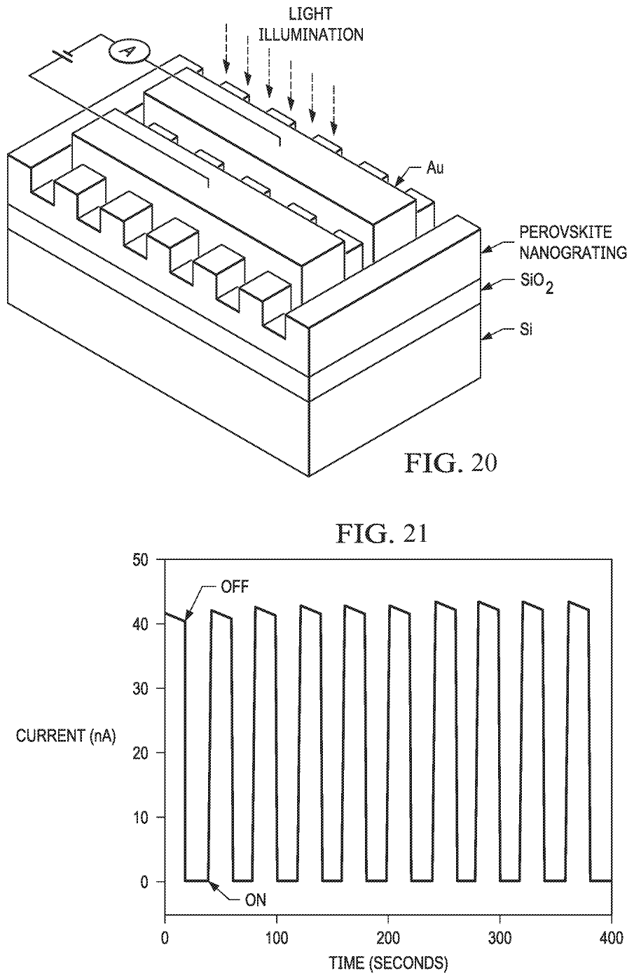

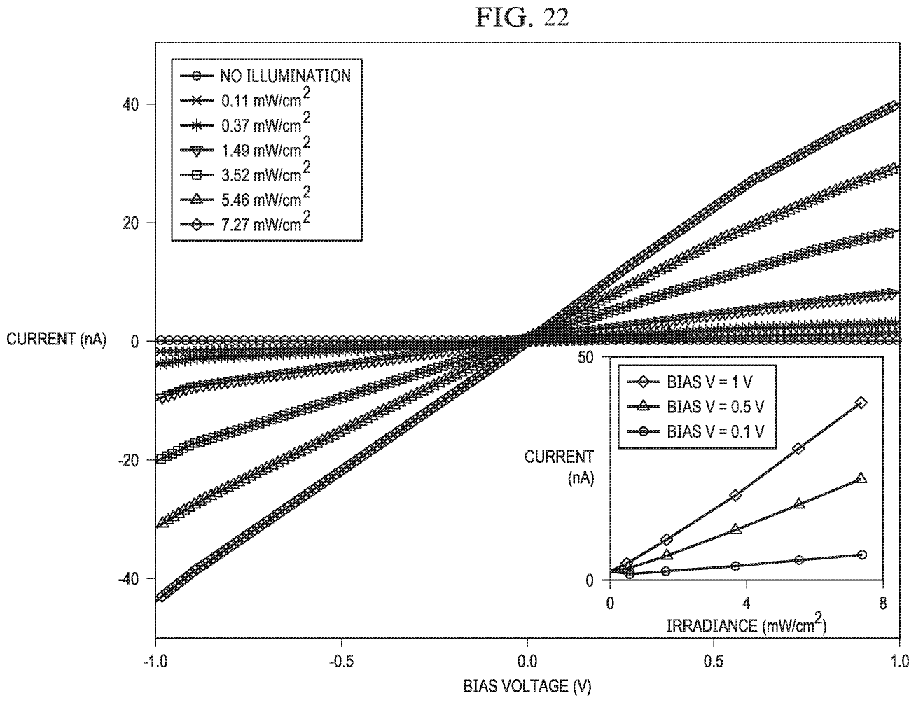

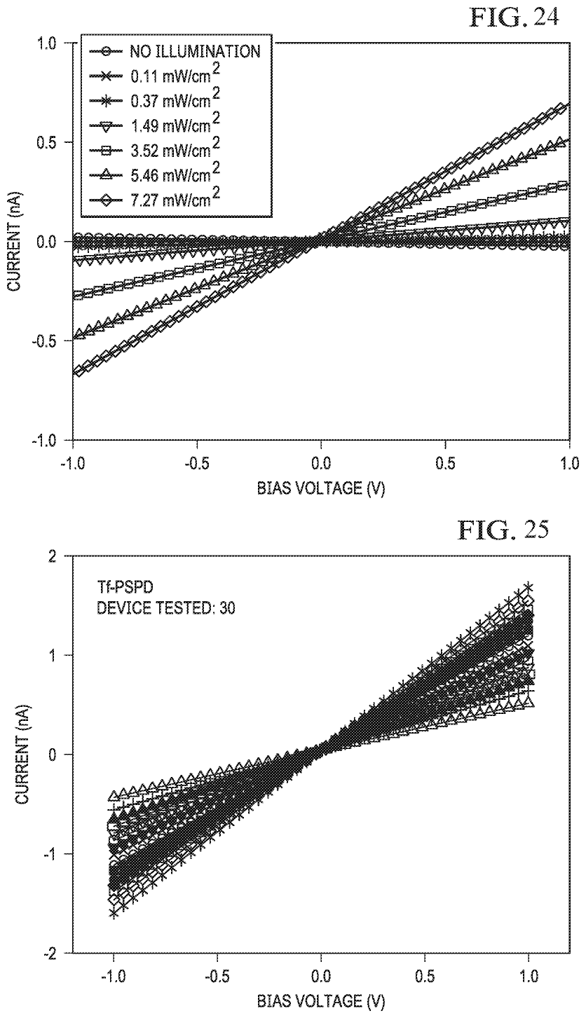

The schematic illustration of a nanograting-PSPD device is also shown FIG. 20. For the nanograting-PSPD device, the electrode pairs were deposited so that the current flow is along the gratings under applied electrical field. FIG. 22 plots the current and bias voltage curve (I-V curve) of the nanograting-PSPD in the dark and under halogen light illumination with irradiance varying from 0.11 to 7.27 mW/cm². The linear current-voltage behavior indicates a good ohmic contact between gold and perovskite. In the dark state, the device has a resistance of tens of gigaohms. Under illumination, large amounts of electron-hole pairs are generated due to photon absorption and are subsequently extracted by the electrical field, which causes a dramatic increase of conductance. At the same voltage, the photocurrent increases gradually with incident light density, as illustrated in the inset graph of FIG. 22. The corresponding I-V curve for the tf-PSPD is presented in FIG. 24.

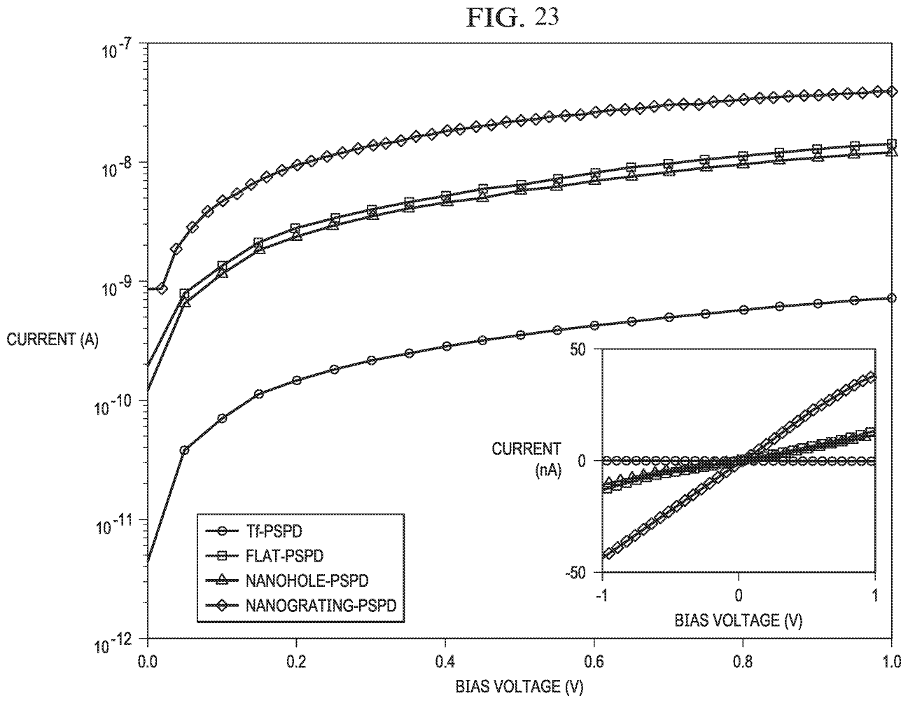

FIG. 21 shows the temporal current of the nanograting-PSPD under 7.27 mW/cm² halogen lamp illumination with a bias of 1 V. The light was switched on and off for 10 cycles during the test. An on/off current ratio of more than 1000 was achieved with a dark current as low as 30 pA while illuminated with a current of more than 40 nA. To compare the optoelectronic performance between the tf-PSPD, flat-PSPD, nanohole-PSPD, and nanograting-PSPD, their I-V characteristics under 7.27 mW/cm² halogen light illumination were plotted in FIG. 23. One can clearly see that under the same conditions the flat-PSPD, nanohole-PSPD, and nanograting-PSPD all exhibit a large improvement in photocurrent compared with the tf-PSPD. The nanograting-PSPD has the highest photocurrent, over 35 times that of the tf-PSPD at a bias of 1 V.

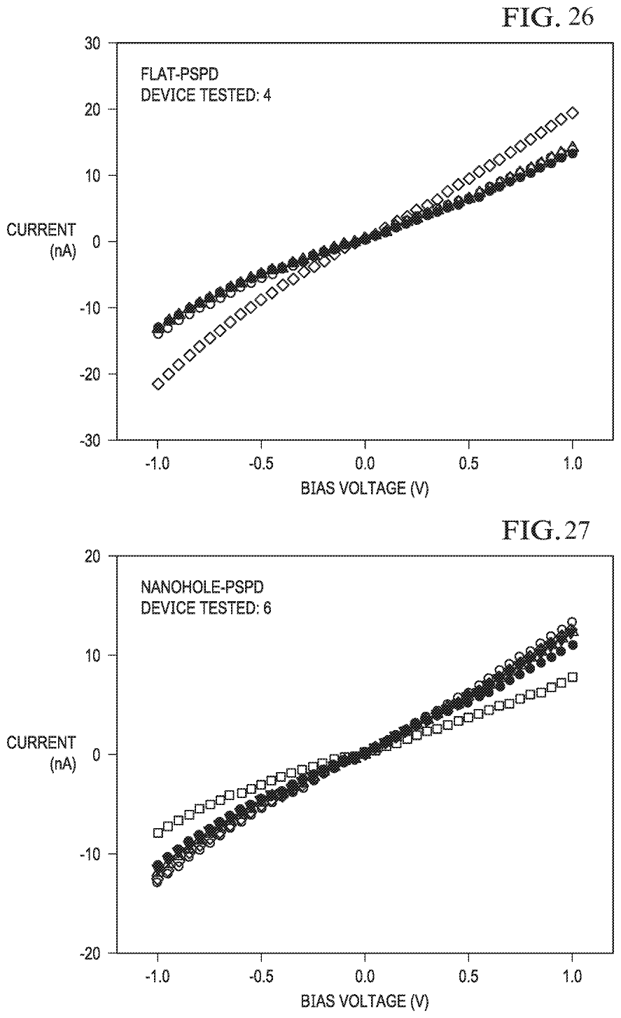

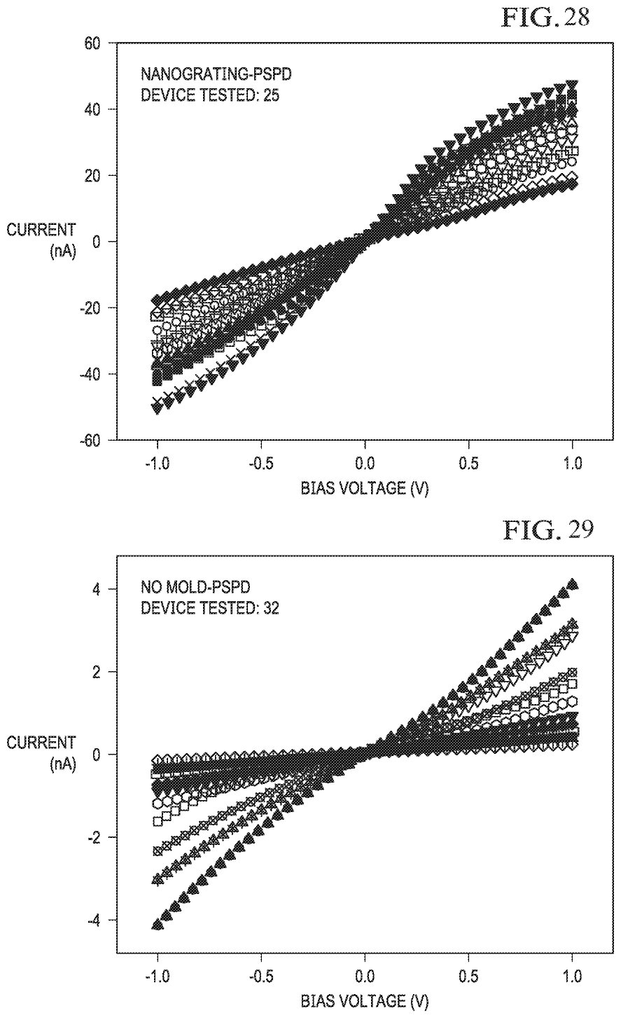

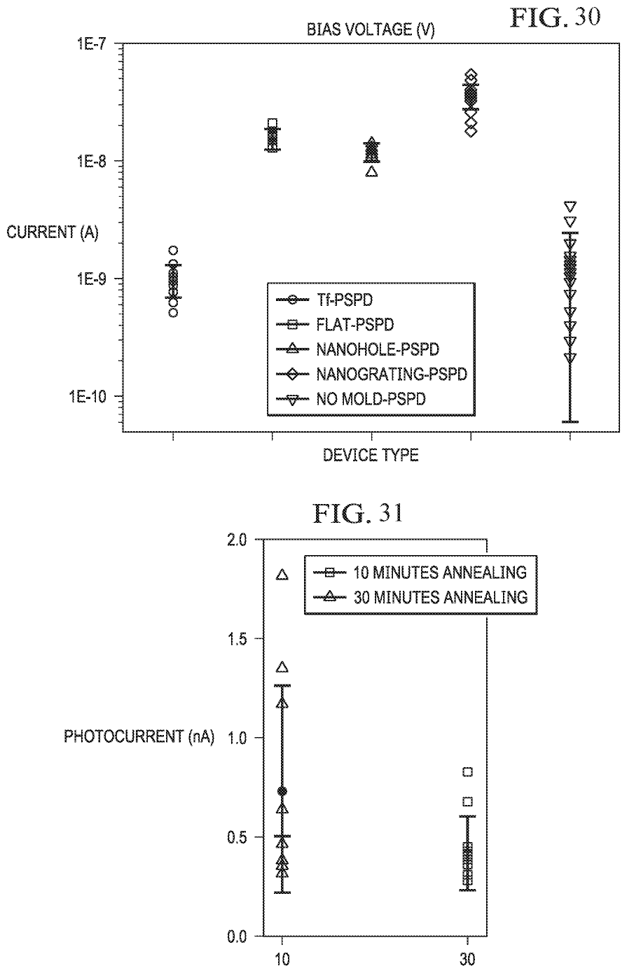

To obtain a more reliable performance comparison, multiple devices were tested for each type. The corresponding I-V curves under 7.27 mW/cm² halogen light illumination are shown in FIGS. 25-28. FIG. 29 shows I-V characteristics of no mold-PSPDs, wherein no mold-PSPD refers to devices formed on the area without Si molds for the same imprinted perovskite sample.

Responsivity is widely used to evaluate the efficiency of a photodetector responding to an optical signal. It is defined as the ratio of the photocurrent to the illumination power, as expressed by

$$R = \frac{{I}_{p h}}{{L}_{light} \times S} \qquad ( 1 )$$

where L_{light} is the incident light power density, S is the effective area, and Iₚₕ represents the photocurrent as given by

Iₚₕ=I_{illuminated}−I_{dark} (2)

where I_{illuminated} and I_{dark} are the current with and without illumination, respectively. Besides responsivity, the on/off ratio that is represented by illuminated current divided by the dark current is another important parameter for photodetectors.

The calculated photodetector parameters along with their geometries are summarized in Table 1. All the nanoimprinted devices showed significantly enhanced performance; that is, the responsivity R and on/off ratio are over 10 times and 5 times higher than those of the nonimprinted devices, respectively.

Particularly, in the dark environment, I_{dark} has also increased by 3 times for the flat-PSPD, 2.4 times for the nanohole-PSPD, and 5 times for the nanograting-PSPD, which should be attributed to the improvement of charge carrier transport in the NIL films under an applied electrical field.

### Example 7

Characterization of the Effects of Thermal Annealing on Nanoimprinted and Nonimprinted Perovskite Photodetectors.

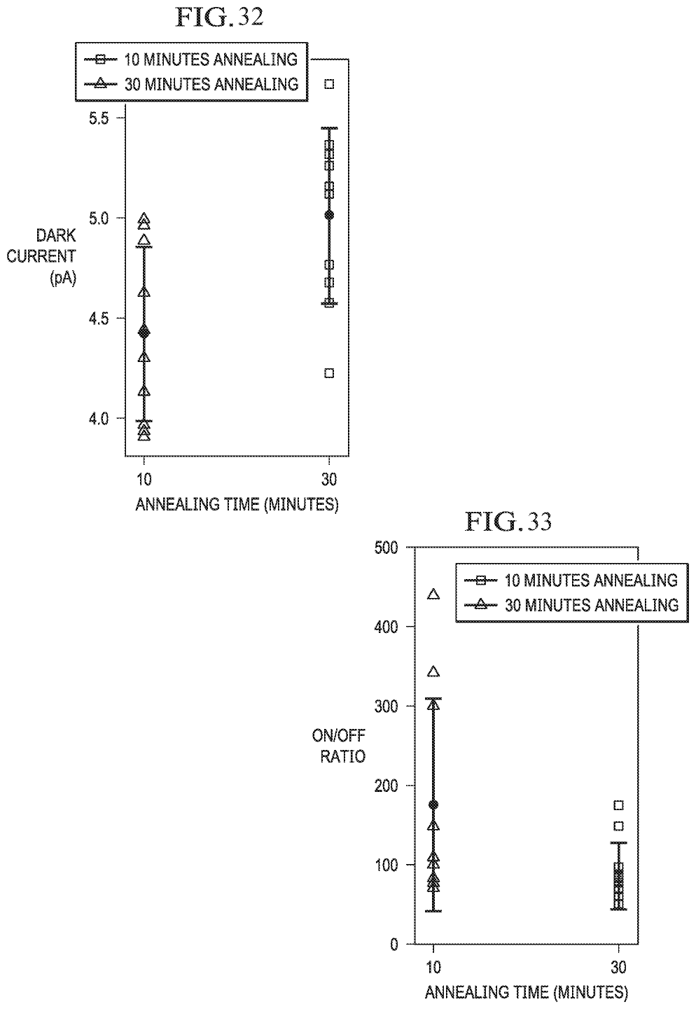

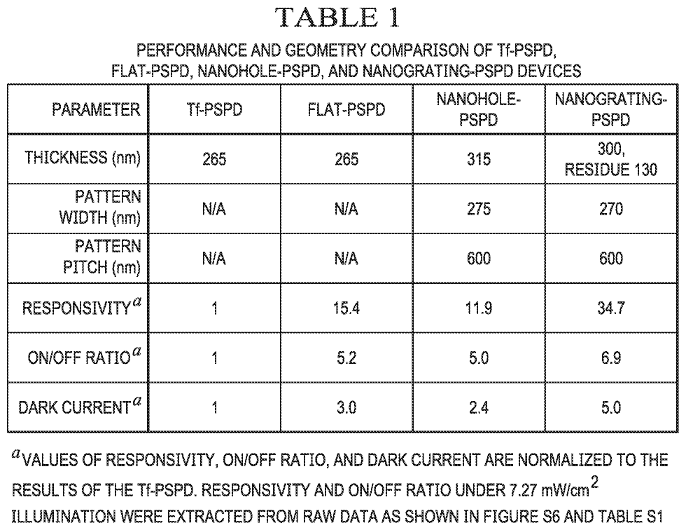

To study whether thermal annealing during NIL was the primary cause of performance enhancement of nanoimprinted devices, another set of perovskite thin-film samples was prepared and the corresponding MSM photodetectors were fabricated. One sample was annealed at 100° C. for 10 min, while another was annealed for 30 min at the same temperature during the perovskite thin-film preparation process. Ten devices were tested for each condition with a bias voltage of 1 V. Their photodetector performance was characterized and is presented in FIGS. 31-33. The devices with 30 min annealing show relatively worse performance, suggesting possible degradation due to long-time thermal treatment. The results indicate that the improvement of nanoimprinted devices was caused by the combined effect of elevated pressure and temperature during NIL, especially with confined nanostructures. The improved crystallinity of the imprinted perovskite film is likely a primary cause of the performance enhancement for the nanoimprinted photodetectors.

Several processes including photon absorption, electron-hole generation, carrier transport, and recombination were utilized to assess photodetector performance. The results of SEM (FIGS. 5-9) and XRD (FIG. 10) have shown that NIL has induced the formation of larger and ordered grains, and thus the crystallinity of perovskite has improved, which plays a positive role in multiple processes.

First, the carrier transport and mobility would increase, as the charge carriers encounter less scattering at the grain boundaries or defects. Therefore, both the illuminated current and dark currents increase significantly in the NIL imprinted samples. Second, electron-hole recombination lifetime may lengthen, as verified through PL lifetime tests (FIG. 14). Improvements in both mobility and carrier lifetime contribute to longer diffusion length. These effects contribute to the dramatically improved photocurrent and thus responsivity for the nanoimprinted photodetectors.

The comparable on/off ratio between the flat-PSPD and nanohole-PSPD indicates that charge carrier transport might be the primary cause of the inferior performance of the nanohole-PSPD. The vertical nanohole arrays could hinder the carrier transport since the charge carriers suffer from severe surface scattering driven by the electrical field. The gratings, on the other hand, largely enhanced the carrier transport due to well-aligned conductive channels along the electrical field and ordered crystal grains to reduce surface and grain boundary scattering. The nanograting structure is also suitable for photon management due to the one-dimensional photonic band gap effect. Therefore, the nanograting-PSPDs deliver the best performance in these samples with 35-fold higher responsivity and 7-fold higher on/off current ratio than the tf-PSPD. It is noted that due to the limitation of the mold depth, the nanograting-PSPD has a residual layer of 130 nm that also contributes to the total device current.

From the SEM images of FIGS. 8 and 9, the residual layer may not have a high crystallinity as compared to the gratings. Therefore, it is reasonable to assume that the residual layer has a similar performance to that of the flat-PSPD, and its contribution to the total current should be less than 20%. By further optimizing the mold depths, we expect the residual layer-free nanogratings to have even higher performance.

### Example 8

High-Performance Perovskite Nanograting Photodetectors.

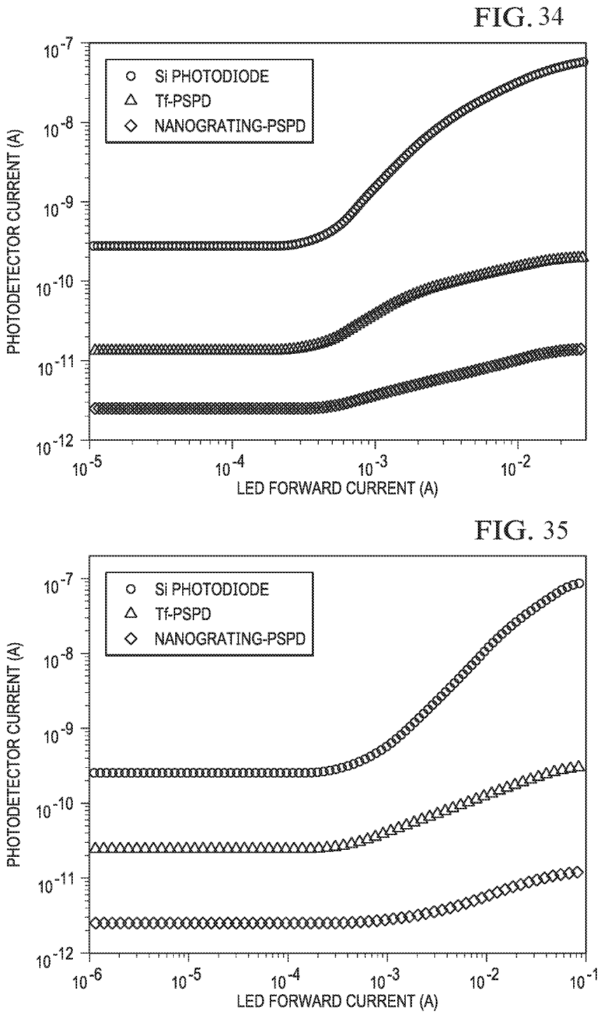

To further evaluate the nanograting-PSPDs, they were tested along with the tf-PSPD under monochromatic LED illumination. The currents of the nanograting-PSPD, tf-PSPD, and a commercial Si photodiode were measured and plotted against the LED forward current in FIGS. 34 and 35. Both the tf-PSPD and nanograting-PSPD were biased at 1 V, while the Si photodiode was reverse biased at 10 V. The nanograting-PSPD shows much higher current than the tf-PSPD. The Si photodiode has an effective radiation sensitive area of 2.84 mm×2.84 mm and was used to calibrate the irradiance. One should note that the Si photodiode has the largest current, as its effective radiant-sensitive area is over 3000 times that of our perovskite photodetectors, while the current per effective illuminated area under the same irradiance is of concern here.

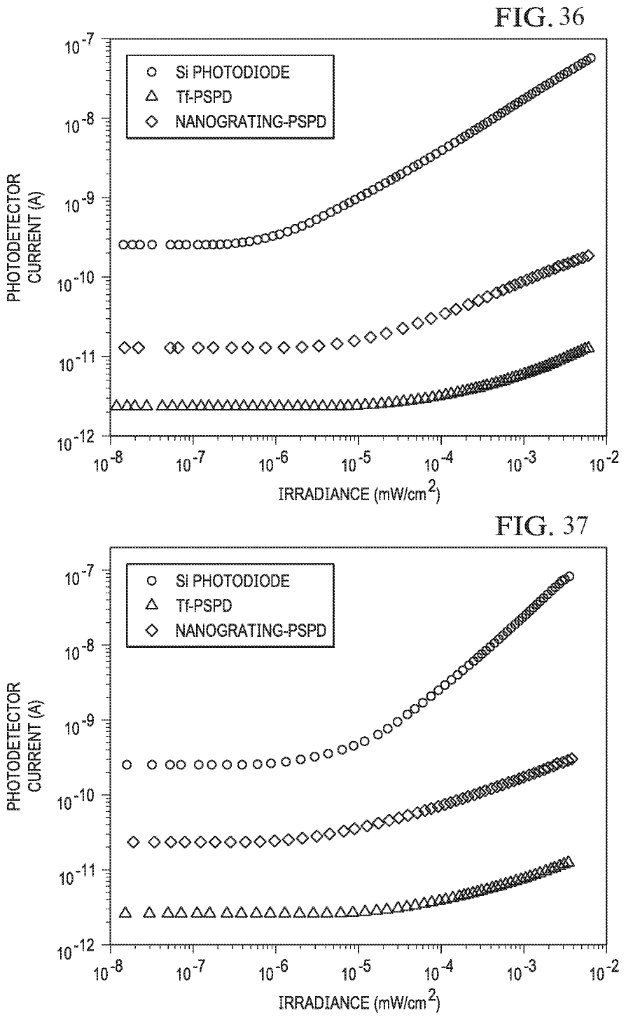

The irradiance was evaluated with the Si photodiode, and the corresponding photodetector current versus irradiance is plotted in FIGS. 36 and 37. FIG. 36 shows a plot of photodetector current vs irradiance at λ=466 nm. FIG. 37 shows a plot of photodetector current vs irradiance at λ=635 nm. The irradiance was evaluated with the Si photodiode, which has a responsivity of 0.12 A/W at λ=466 nm and 0.3 A/W at λ=635 nm. The lowest irradiance was chosen to be the three sigma value of the Si photodetector dark current distribution.

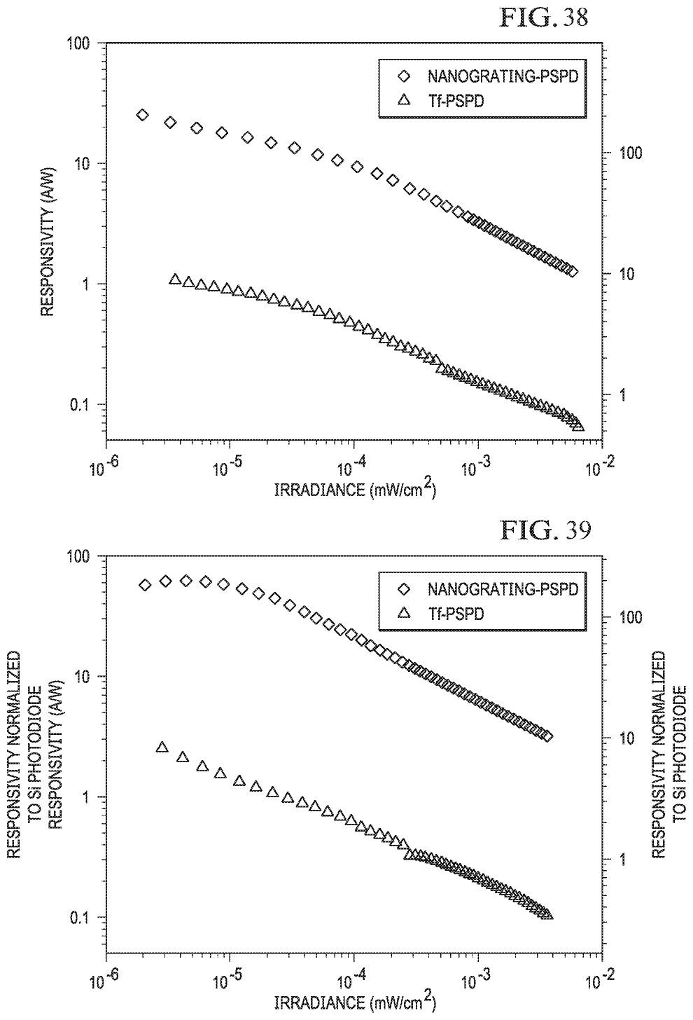

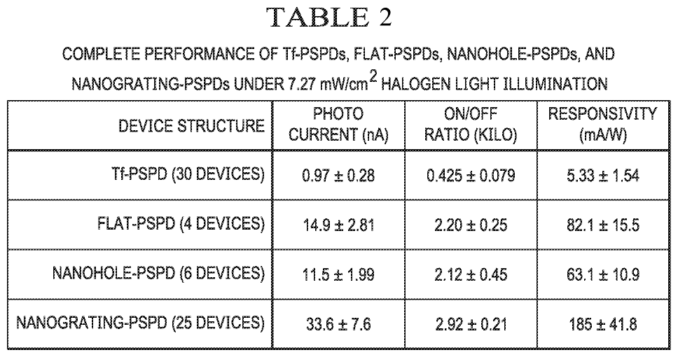

FIGS. 38 and 39 show the calculated photodetector responsivity versus irradiance at λ=466 nm (FIG. 38) and λ=635 nm (FIG. 39) with a bias voltage of 1 V. It is observed that generally with a decrease in the light intensity the responsivity increased. The upper curve represents the nanograting-PSPD and the lower curve represents the tf-PSPD, and both perovskite photodetectors were biased at 1 V, while the Si photodiode was reverse biased at 10 V. The results were in agreement with the literature. The performance of the nanograting-PSPD was superior to that of the tf-PSPD, similar to the results of the halogen light illumination tests. At λ=466 nm (FIG. 38), the tf-PSPD has only R=0.16 A/W, while the nanograting-PSPD has R=3.23 A/W Under 1 μW/cm² illumination. With 2 nW/cm² irradiance, the nanograting-PSPD has R=24.1 A/W, which is 100 times that of the commercial Si photodiode (0.12 A/W).

Similarly, at an illumination of λ=635 nm (FIG. 39), the nanograting-PSPD has R=6.2 A/W, which is over 30 times that of the tf-PSPD and 20 times that of the commercial Si photodiode under 1 μW/cm² irradiance. The right y-axis illustrates the relative responsivity normalized to the Si photodiode. At 4.5 nW/cm² irradiance, the responsivity of the nanograting-PSPD has increased to 58.5 A/W, which is 100 times more than that of the commercial Si photodiode (0.3 A/W). Both devices show better response at λ=635 nm than at 466 nm. The imprinted nanograting-PSPDs also outperform the previously reported hybrid perovskite nanowire and thin-film photodetectors.

In summary, we report the use of nanoimprint lithography to define ordered perovskite nanostructures as active device areas, while NIL simultaneously improves their crystallinity and optoelectronic performance. NIL was conducted on perovskite thin films with flat, nanopillar, and nanograting molds. Planar metal-semiconductor-metal photodetectors were fabricated on the perovskite films with different morphologies, and their optoelectronic performance was characterized. All of the nanoimprinted devices demonstrated significantly improved performance compared to non-imprinted devices, while the nanograting devices are the best with an average of 35 times improvement in responsivity and 7 times improvement in on/off current ratio under 7.27 mW/cm² halogen light illumination.

The nanograting-PSPD has a high responsivity value of 24.1 A/W at 2 nW/cm² LED illumination of λ=466 nm and 58.5 A/W at 4.5 nW/cm² illumination of λ=635 nm with a bias voltage of 1 V. Such performance is about 30 times better than the tf-PSPD and more than 100 times better than the commercial Si photodiode. The performance enhancement is likely due to NIL-induced higher crystallinity; particularly, the nanograting structure is favorable for better photon absorption and charge carrier transport. Further improvement on the nanograting-PSPD performance is expected by optimizing the nanograting geometries and the nanoimprinting conditions. Additionally, nanograting-based photodetectors and solar cells with vertical P-I-N structures are in preparation.

Our study demonstrated that NIL is a simple yet effective way to fabricate high-performance nanoscale optoelectronic devices using emerging hybrid perovskite materials, which are suitable for electronic circuit integration and manufacturing.

Note that prior literature [Saliba M, et al., “Structured Organic-Inorganic perovskite toward a Distributed Feedback Laser”, Adv. Mater. 2016, 28, 923-929] had indicated the difficulty and challenge of producing nanoimprinting organo-metal perovskites for optoelectronic and related photovoltaic applications. Specifically, this paper stated “One very common approach for fabricating organic DFB lasers is the direct nanoimprinting of the active material. [33,35,36] However, it is important to note the distinction between organics (soft materials) and perovskites (hard materials). It is not directly obvious that a technique used to enable lasing in organics would be translatable to perovskites. Indeed, it still remains an open challenge to demonstrate direct nanoimprinting of perovskite films.” Thus, the known art has recognized an intractable problem solved by the illustrative embodiments.

Further evidence of the difficulty of direct imprinting of perovskite comes from our DSC measurements of perovskite glass transition temperature. Nanoimprint typically requires the material to be imprinted to have a glass transition temperature so that imprinting above such temperature would be successful as the material would be soft enough to flow. The DSC experiment demonstrates that perovskite does not have glass transition behavior, indicating that it is not imprintable.

Our success of direct imprint of perovskite stems from the fundamental understanding that perovskite may be flexible to flow in a “grain-sliding” model, which is different from that of polymer that has a glass transition behavior. As described above, under pressure and heat, perovskite grains can slide and merge to fill the cavities of the mold, as we demonstrated successfully for the first time.

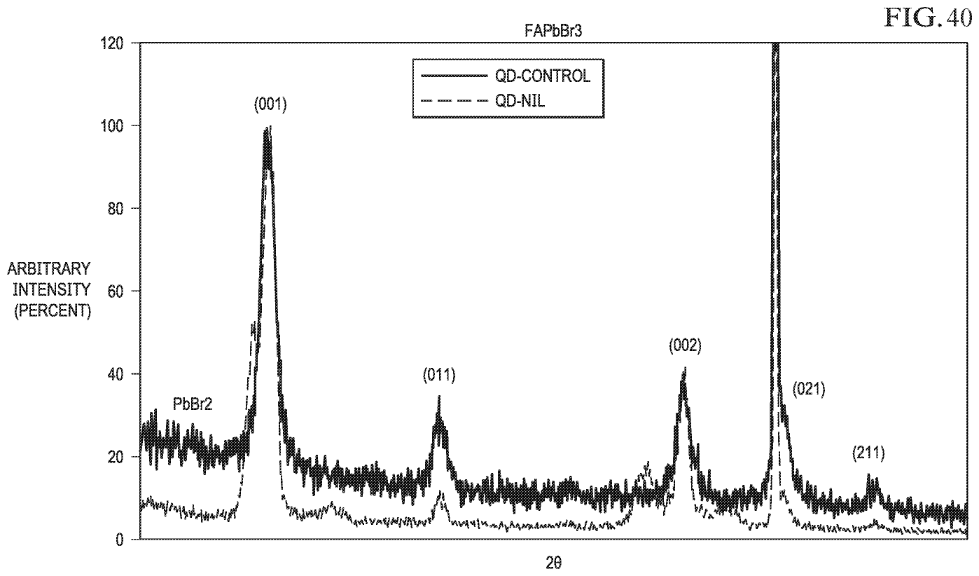

FIG. 40 is provided in the context of an additional example, example 9, relative to the above examples. Example 9 relates to nanoimprint of perovskite quantum dots. This particular example is perovskite quantum dots, as the material has many tiny “grains”, known as quantum dots that allow the perovskite to move and fill the molds according to our grain-sliding model. This behavior allows the perovskite material to be directly imprinted to form precise structures at nanoscale.

The material is first prepared with the following way. A 0.3 molar solution of FAPbBr3 was made with DMF as the solvent. Then, n-Butylammonium Bromide (BABr) was added to the perovskite solution so that a molar ratio of 2:10 between BABr:FAPbBr3 was achieved. The material was then spincoated at 4500 RPM for 1 minute. 300 uL of toluene was dropped on the spinning film after 4 seconds from the start of the spincoating process. Glass or Si was used as the substrate. The samples were then imprinted at 100° C., 7 MPa, for 20 mins. The structures were well formed, and then we did the XRD measurements of the imprinted sample to study its crystallinity.

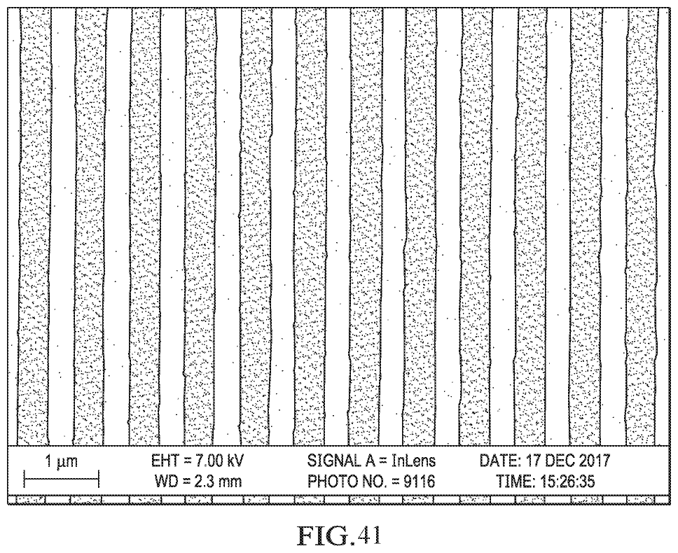

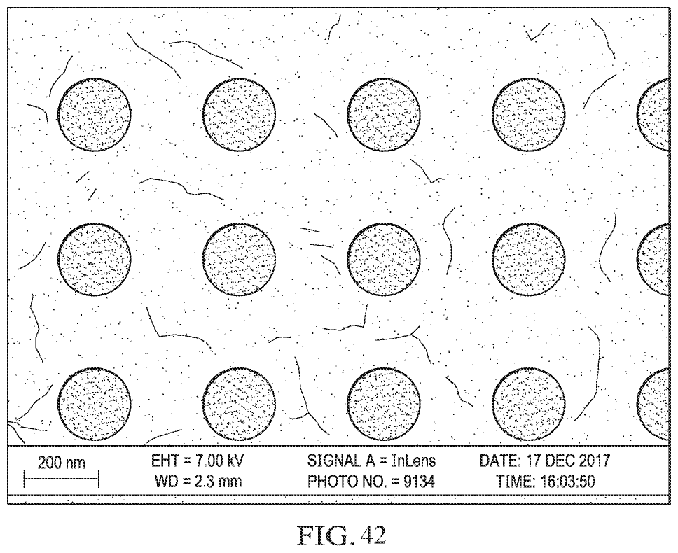

FIG. 41 is a representation of an electron microscope image of an imprinted perovskite quantum dot sample with formed nanograting. FIG. 42 is a representation of an electron microscope image of an imprinted perovskite quantum dot sample with formed nanoholes. As shown in FIGS. 41 and 42, perovskite quantum dots can be perfectly patterned like polymer materials.

For device application, the patterning itself should not degrade or destroy the key material property. To check that, XRD experiments were performed. FIG. 40 shows that the XRD data of imprinted quantum dots samples which show the new peaks beside (001), (002) peaks of FAPbBr3, indicating the existence of Ruddleson-Popper phase induced by the combination of high pressure and annealing at 100° C. during the NIL process. While 100° C. process does indeed increase the grain size of the quantum dots and induces a Ruddleson popper phase. The Perovskite quantum dot materials have shown great potential for LED applications with high quantum efficiency. We have applied NIL to pattern perovskite quantum dots materials for the first time.

Continuing example 9, we tried to lower the NIL temperature to 60° C. and then to 20° C. (room temperature). It was found that the NIL can be successful even at room temperature. FIG. 41 and FIG. 42 show the electron microscopic images of the imprinted structures at 20 deg. C. Perfectly formed nanogratings and nanoholes were created with NIL.

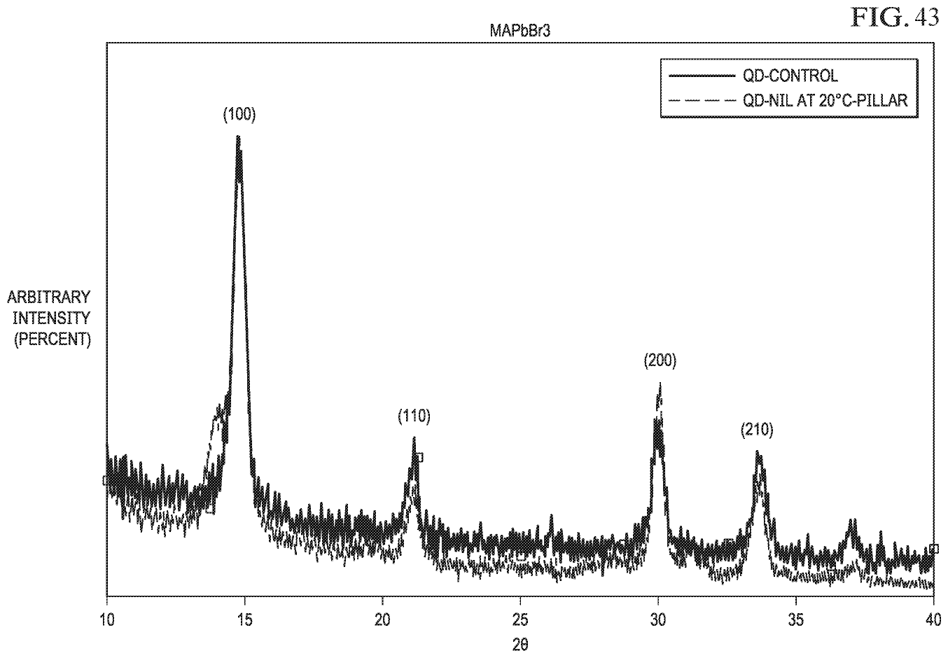

FIG. 43 is a graph of XRD results of the perovskite quantum dot sample imprinted at 20° C. versus a non-imprinted thin film sample as a control. FIG. 43 presents XRD results of these low-temperature imprints show that (100) and (200) peaks that signature the Ruddleson popper phase are similar to that of the control samples.

This result means NIL at room temperature does not degrade the quality of the QD samples. These results also demonstrate that lower temperature imprints should be possible for QD samples likely due to the small sizes of quantum dots make them flowable under pressure even at room temperature. Therefore, the nanostructures can be formed by the pressure alone. More importantly, this process would not induce degradation of material, so that high performance devices can be made out of them.

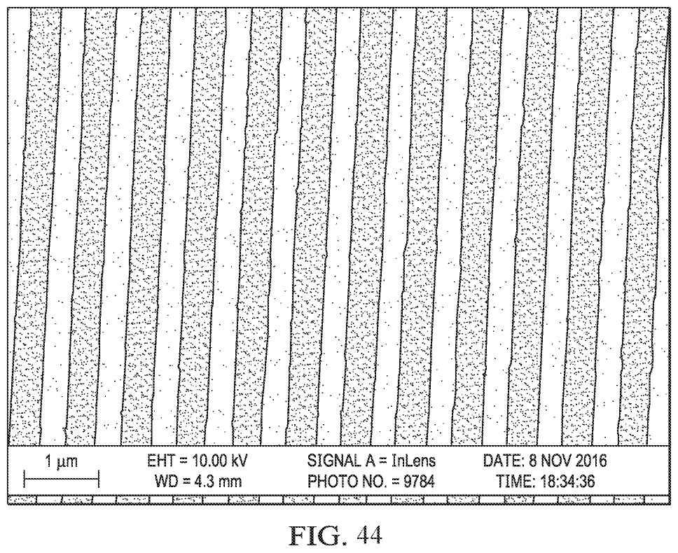

FIG. 44 is a representation of an electron microscope image of an imprinted acetated perovskite sample. FIG. 44 is associated with another example; specifically, example 10. Example 10 relates to a nanoimprint of acetated perovskite material.

We further demonstrated that NIL can be applied to imprint acetated perovskite material. For acetate perovskite, the samples were prepared as follows: a weight 91 mg of MAAC was placed in a glass vial and then 1.1 mL of Pbi2:MAI 1M was added in DMF ink to the glass vial. The resulting ink was stirred for 30 mins at room temperature, and the resulting solution was filtered using a 0.45 μm PTFE filter into another vial. Silicon substrates were cleaned and exposed to UV light for 15 mins. They were then transferred into a nitrogen glovebox and spincoated with the filtered ink at 5000 rpm for 60 s. Subsequent to spincoating, the samples were annealed at 100° C. for 5 mins in a hood where relative humidity was maintained at 35%. The samples were then imprinted at 100° C. and at 7 MPa for 20 mins after 24 hours of spincoating.

FIG. 44 is the representation of an optical microscope image of an imprinted acetated perovskite sample, showing high quality pattern transfer.

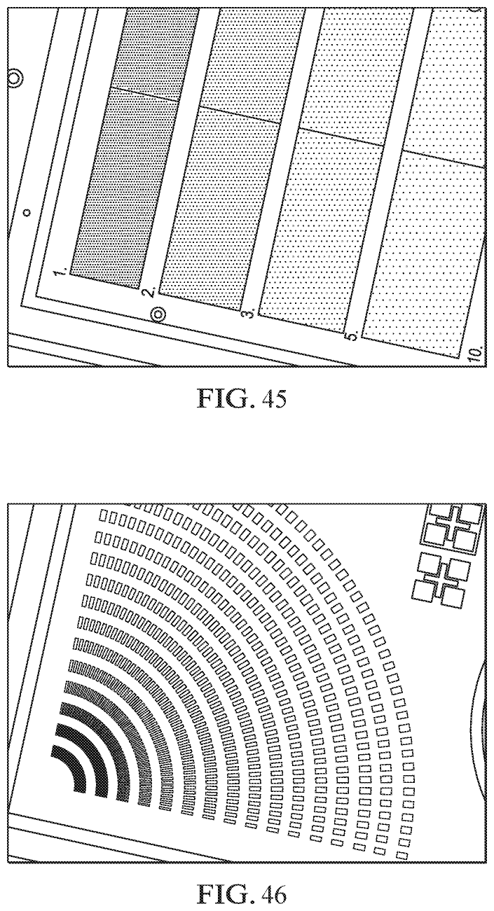

FIG. 45 is a representation of an electron microscope image of an imprinted perovskite PVP composite sample. FIG. 45 is associated with another example; specifically, example 11. Example 11 relates to a nanoimprint of perovskite PVP composite material.

For the MAPbI3 perovskite PVP composite, the samples were prepared by mixing 1.5 molar solution of CH3NH3PbI3 and PVP (50% weight) and heated on a hot plate. Once a homogeneous mixture was formed, the solution was spincoated on top of a glass substrate. Dry toluene was dropped half way through the spincoating. The NIL was performed for 10 mins at 100 C and 70 bar of pressure. FIG. 45 and FIG. 46 show the optical microscopic images of the imprinted structures of various shapes at 1-10 μm. As can be seen, high definition formations of nanogratings were created with NIL in perovskite PVP composite for the first time.

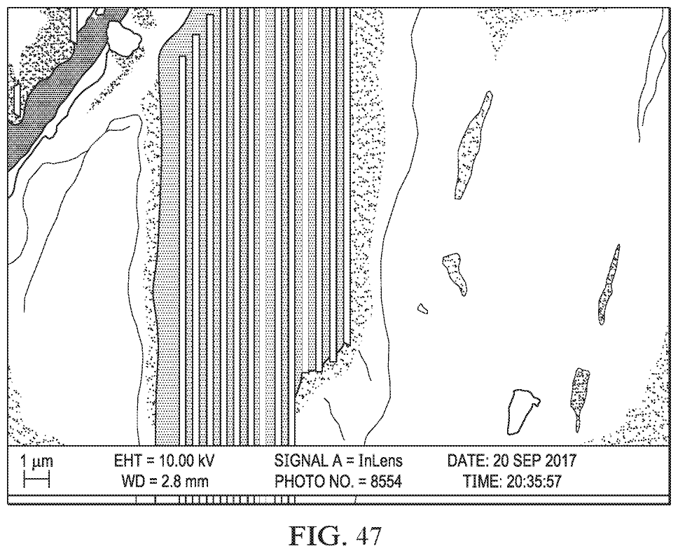

FIG. 47 is a representation of an electron microscope image created by nanoimprint lithography (NIL) of a single crystal perovskite. FIG. 47 is related to another example, example 12. Example 12 relates to a nanoimprint of a single-crystalline perovskite.

The single crystalline perovskite sample of MAPb(Br2-I1) shown in FIG. 47 was first polished with 600 grade and 1200 grade sand paper. Immediately after polishing, the sample was imprinted at 100° C. and at 7 MPa for 20 mins. FIG. 47 shows a representation of an actual electron microscopic image of the imprinted gratings. Very well formed nanogratings were created with NIL. This method demonstrates a feasible way to shape single crystalline perovskite that is synthesized chemically to regular structures, which is important for creating useful devices, such as photodetectors and other microelectromechanical devices.

Still other examples are possible. Some additional examples are as follows.

A method for making a nanoimprinted perovskite thin film, the method comprising: applying a solution onto a substrate thereby forming a precursor film, the solution comprising an organometal halide in a volatile solvent; fabricating a damp thin-film, wherein fabricating the damp thin-film includes annealing the precursor film, thereby partially evaporating the volatile solvent; imprinting the damp thin film with a mold; and separating the mold from the imprinted thin-film.

The organometal halide is selected from a group consisting of methylammonium lead triiodide (CH3NH3PbI3 or MAPbI3), methylammonium lead tribromide (CH3NH3PbBr3 or MAPbBr3), formamidinium lead triiodide (NH2CHNH2PbI3 or FAPbI3), formamidinium lead tribromide (NH2CHNH2PbI3 or FAPbBr3), or mixtures thereof.

Applying a solution onto a substrate includes at least one of spin coating, screen printing; spraying, and inkjet printing. [those are all technical names already

Applying a solution onto a substrate includes forming a precursor film.

The volatile solvent is a non-aqueous organic solvent.

The non-aqueous solvent is an acetate-based solvent.

The non-aqueous solvent is selected from a group consisting of N,N′-dimethyl sulfoxide (DMSO), dimethylformamide (DMF), and a γ-butyrolactone:N,N′-dimethyl sulfoxide mixture.

The damp thin-film is a perovskite thin-film.

The damp thin film is composed of quantum dots of perovskite, or the damp thin film is a composite of perovskite with polyelectrolyte or other polymer matrix.

The mold is coated with an anti-adhesive.

The mold is comprises at least one of a group consisting of silicon, silicon dioxide, polydimethylsiloxane (PDMS), intermediate polymer stamp (IPS), and metal, such as Al, stainless steel or Cu.

The mold is selected from a group of microscale and/or nanoscale structures consisting of pillars, holes, and gratings.

Imprinting the damp thin film includes pressing a mold onto the damp thin-film.

Imprinting the damp thin film further includes heating the imprinted thin-film starting from 40 C [small pressure of 0.1 Mpa.

Imprinting the damp thin-film further includes increasing the pressure by increments and increasing the temperature by increments.

Imprinting the damp thin-film further includes increasing the pressure at increments of between 0.5 MPa and 3 MPa and increasing the temperature at increments of between 5° C. to 40° C.

Imprinting the damp thin-film further includes increasing the pressure up to 7 MPa and increasing the temperature up to 130° C.

Applying toluene onto the precursor film before annealing.

Annealing comprises heating at a temperature of between 80° C. and 120° C. for between 5 minutes to 60 minutes.

A photodetector device comprising: two metal layers and an imprinted thin-film organometal perovskite layer, wherein the imprinted thin-film layer is sandwiched between the two metal layers and wherein the imprinted thin-film layer is fabricated using the methods of claims 1-18.

A photovoltaic device comprising: two electrically conductive electrode layers, wherein one of the electrode layers is optionally transparent; two transport layers adjacent to the conductive electrode layers, wherein the transport layers are a hole transport layer (HTL) and electron transport layer (ETL); and an imprinted thin-film organometal perovskite layer, wherein the imprinted thin-film organometal layer is sandwiched between the two transport layers, and wherein the imprinted thin-film perovskite layer is fabricated using the methods described above.

A light emitting device (LED) comprising: two electrically conductive electrode layers, wherein one of the electrode layers is optionally transparent; two transport layers adjacent to the conductive electrode layers, wherein the transport layers are a hole transport layer (HTL) and electron transport layer (ETL); and a light-emissive imprinted thin-film organometal perovskite layer, wherein the imprinted thin-film organometal layer is sandwiched between the two transport layers, the conductive electrode layers are configured for charge injection into the light emissive imprinted thin-film organometal perovskite layer and wherein the imprinted thin-film perovskite layer is fabricated using the methods described above.

Yet other examples are possible. For example, the illustrative embodiments also contemplate the following examples.

A method for making a nanoimprinted perovskite film or a perovskite crystal comprising: applying a solution onto a substrate, thereby forming a precursor film or a precursor crystal, wherein the solution comprises an organo-metal halide precursor in a solvent; fabricating an organo-metal halide perovskite film or an organo-metal halide perovskite crystal, wherein fabricating includes annealing the precursor film or the precursor crystal, thereby at least partially evaporating the solvent; imprinting the organo-metal halide perovskite film or the organo-metal halide perovskite crystal with a mold, thereby forming an imprinted film or an imprinted crystal; and separating the mold from the imprinted film or the imprinted crystal, thereby forming the perovskite film or the perovskite crystal.

The organo-metal halide perovskite film or the organo-metal halide perovskite crystal consists of the organo-metal halide perovskite film, wherein the organo-metal halide perovskite film has a thickness of about 50 nanometers to about 100 micrometers, and wherein the perovskite film comprises a nanoimprinted perovskite film.

The organo-metal halide perovskite film or the organo-metal halide perovskite crystal is damp during fabrication.

The solvent comprises an acetate-based organic solvent.

The solvent is selected from the group consisting of: N,N′ dimethyl sulfoxide (DMSO), dimethylformamide (DMF), and a γ-butyrolactone:N,N′-dimethyl sulfoxide mixture (GBL-DMSO).

The organometal halide of the organo-metal halide perovskite is selected from the group consisting of: methylammonium lead triiodide (CH3NH3PbI3 or MAPbI3), methylammonium lead tribromide (CH3NH3PbBr3 or MAPbBr3), formamidinium lead triiodide (NH2CHNH2PbI3 or FAPbI3), formamidinium lead tribromide (NH2CHNH2PbBr3 or FAPbBr3), and mixtures thereof.

Applying the solution onto the substrate includes at least one of spin coating, screen printing, spraying, and inkjet printing.

The mold is coated with an anti-adhesive layer.

The mold comprises microscale or nanoscale structures, and wherein the microscale or nanoscale structures include at least one of pillars, holes, or gratings.

The organo-metal halide perovskite film or the organo-metal halide perovskite crystal is composed of quantum dots of perovskite.

The organo-metal halide perovskite film or the organo-metal halide perovskite crystal is composed of a composite in which perovskite is mixed with a polymer.

The polymer matrix comprises a solid polyelectrolyte, such as polyvinilpyrolidone (PVP), polyethylene glycol (PEG) or polyethylene oxide (PEO).

The mold comprises at least one of the group consisting: of silicon, silicon dioxide, polydimethylsiloxane (PDMS), fluoropolymer, and a metal.

Imprinting the film includes pressing the mold onto the film.

Imprinting the film further includes heating the film under pressure.

Imprinting the film further includes increasing the pressure by increments and increasing a temperature of the film by increments.

Imprinting the film further includes increasing the pressure at increments of between 0.5 MPa and 3 MPa and increasing the temperature comprises increasing the temperature at increments of between 5° C. to 40° C.

Applying an antisolvent onto the precursor film before annealing.

Annealing comprises heating at a temperature of between 80° C. and 120° C. for between 1 minutes to 60 minutes.

A nanoimprinted device comprising: an imprinted organometal perovskite layer comprising one of a film and a crystal. The device can further comprise two metal layers, wherein the imprinted organometal perovskite layer is sandwiched between the two metal layers, thereby forming a photodetector.

A photovoltaic device comprising: two electrically conductive electrode layers; two transport layers respectively adjacent to the electrically conductive electrode layers, wherein at least one of the electrode layers is optically transparent, and wherein the two transport layers are a hole transport layer (HTL) and an electron transport layer (ETL); and an imprinted organometal photoactive perovskite layer, wherein the imprinted organometal perovskite layer is sandwiched between the two transport layers.

At least one of the two transport layers is transparent in a visible spectrum of light.

A light emitting device (LED) comprising: two electrically conductive electrode layers, wherein at least one of the electrode layers is optically transparent; two transport layers respectively adjacent to the two electrically conductive electrode layers, wherein the two transport layers are a hole transport layer (HTL) and electron transport layer (ETL); and a light emissive imprinted organometal perovskite layer, wherein the light-emissive imprinted organometal perovskite layer is sandwiched between the two transport layers, and wherein the two electrically conductive electrode layers are configured for charge injection into the light emissive imprinted organometal perovskite layer.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A method for making a nanoimprinted perovskite film or a perovskite crystal, the method comprising:
applying a solution onto a substrate, thereby forming a precursor film or a precursor crystal, wherein the solution comprises an organo-metal halide precursor in a solvent;
fabricating an organo-metal halide perovskite film or an organo-metal halide perovskite crystal, wherein fabricating includes annealing the precursor film or the precursor crystal, thereby at least partially evaporating the solvent;
imprinting the organo-metal halide perovskite film or the organo-metal halide perovskite crystal with a mold, thereby forming an imprinted film or an imprinted crystal; and
separating the mold from the imprinted film or the imprinted crystal, thereby forming the nanoimprinted patterned perovskite film or the perovskite crystal.

2. The method of claim 1, wherein the organo-metal halide perovskite film or the organo-metal halide perovskite crystal consists of the organo-metal halide perovskite film, wherein the organo-metal halide perovskite film has a thickness of about 50 nanometers to about 100 micrometers, and wherein the perovskite film comprises a nanoimprinted perovskite film.

3. The method of claim 1, wherein the organo-metal halide perovskite film or the organo-metal halide perovskite crystal is damp during fabrication.

4. The method of claim 1, wherein the solvent comprises an acetate-based organic solvent.

5. The method of claim 1, wherein the solvent is selected from the group consisting of: N,N′ dimethyl sulfoxide (DMSO), dimethylformamide (DMF), and a γ-butyrolactone:N,N′-dimethyl sulfoxide mixture (GBL-DMSO).

6. The method of claim 1, wherein the organometal halide of the organo-metal halide perovskite is selected from the group consisting of: methylammonium lead triiodide (CH3NH3PbI3 or MAPbI3), methylammonium lead tribromide (CH3NH3PbBr3 or MAPbBr3), formamidinium lead triiodide (NH2CHNH2PbI3 or FAPbI3), formamidinium lead tribromide (NH2CHNH2PbBr3 or FAPbBr3), and mixtures thereof.

7. The method of claim 1, wherein applying the solution onto the substrate includes at least one of spin coating, screen printing, spraying, slot die coating and inkjet printing.

8. The method of claim 1, wherein the mold is coated with an anti-adhesive layer.

9. The method of claim 8, wherein the mold comprises microscale or nanoscale pattern structures, and wherein the microscale or nanoscale pattern structures include at least one of periodic or arbitrary pillars, holes, or gratings.

10. The method of claim 1, wherein the organo-metal halide perovskite film or the organo-metal halide perovskite crystal is composed of quantum dots of perovskite.

11. The method of claim 1, wherein the organo-metal halide perovskite film or the organo-metal halide perovskite crystal is composed of a composite in which perovskite is mixed with a functional polymer.

12. The method of claim 11, wherein the polymer matrix comprises a solid polyelectrolyte, such as polyvinilpyrolidone (PVP), polyethylene glycol (PEG), polyethylene oxide (PEO), or a solid polymeric piezoelectric, such as Polyvinylidene fluoride (PVDF).

13. The method of claim 1, wherein the mold comprises at least one of the group consisting: of silicon, silicon dioxide, polydimethylsiloxane (PDMS), fluoropolymer, and a metal.

14. The method of claim 1, wherein imprinting the film includes pressing the mold onto the film.

15. The method of claim 14, wherein imprinting the film further includes heating the film under pressure.

16. The method of claim 15, wherein imprinting the film further includes increasing the pressure by increments and increasing a temperature of the film by increments.

17. The method of claim 16, wherein imprinting the film further includes increasing the pressure at increments of between 0.5 MPa and 3 MPa and increasing the temperature comprises increasing the temperature at increments of between 5° C. to 40° C.

18. The method of claim 1, further comprising:
applying an antisolvent, such as toluene, onto the precursor film before annealing.

19. The method of claim 1, wherein annealing comprises heating at a temperature of between 80° C. and 120° C. for between 1 minutes to 60 minutes.

20. A nanoimprinted device comprising:
an imprinted organometal perovskite layer comprising one of a film and a crystal.

21. The nanoimprinted device of claim 20 further comprising:
two metal layers, wherein the imprinted organometal perovskite layer is either sandwiched between the two metal layers, or located below two metal electrodes, acting as source and drain lateral electrodes, thereby forming a photodetector.

22. A photovoltaic device comprising:
two electrically conductive electrode layers;
two transport layers respectively adjacent to the electrically conductive electrode layers, wherein at least one of the electrode layers is optically transparent, and wherein the two transport layers are a hole transport layer (HTL) and an electron transport layer (ETL); and
an imprinted organometal photoactive perovskite layer, wherein the imprinted organometal perovskite layer is sandwiched between the two transport layers.

23. The photovoltaic device of claim 22 wherein at least one of the two transport layers is transparent in a visible spectrum of light.

24. A light emitting device (LED) comprising:
two electrically conductive electrode layers, wherein at least one of the electrode layers is optically transparent;
two transport layers respectively adjacent to the two electrically conductive electrode layers, wherein the two transport layers are a hole transport layer (HTL) and electron transport layer (ETL); and
a light emissive imprinted organometal perovskite layer, wherein the light-emissive imprinted organometal perovskite layer is sandwiched between the two transport layers, and wherein the two electrically conductive electrode layers are configured for charge injection into transport layers and further injection into the light emissive imprinted organometal perovskite layer.
